(19) United States
(12) Patent Application Publication
(10) Pub. No.: US 2016/0013424 A1
(43) Pub. Date: Jan. 14, 2016

(54) PHOTOELECTRIC CONVERSION ELEMENT AND METHOD OF USING SAME, OPTICAL SENSOR AND IMAGE SENSOR

(71) Applicant: FUJIFILM CORPORATION, Tokyo (JP)

(72) Inventors: Yosuke YAMAMOTO, Kanagawa (JP); Tomoaki YOSHIOKA, Kanagawa (JP); Takahiko ICHIKI, Kanagawa (JP)

(73) Assignee: FUJIFILM CORPORATION, Tokyo (JP)

(21) Appl. No.: 14/862,998

(22) Filed: Sep. 23, 2015

Related U.S. Application Data
(63) Continuation of application No. PCT/JP2014/058204, filed on Mar. 25, 2014.

(30) Foreign Application Priority Data
Mar. 27, 2013 (JP) 2013-066496
Nov. 11, 2013 (JP) 2013-233105

(51) Int. Cl. H01L 51/00

(52) U.S. Cl. CPC H01L 51/0072; H01L 51/0058; H01L 51/0067; H01L 51/0094; H01L 51/0068; H01L 51/0071; H01L 51/0073; H01L 51/442

(57) ABSTRACT

A photoelectric conversion element exhibiting excellent responsiveness and high photoelectric conversion efficiency, a method of using the photoelectric conversion element, and an optical sensor and an image sensor including the photoelectric conversion element are provided. The photoelectric conversion element includes a conductive film, a photoelectric conversion film containing a photoelectric conversion material and a transparent conductive film. The conductive film, the photoelectric conversion film and the transparent conductive film are formed in this order. The photoelectric conversion material contains a compound (A) represented by formula (1):

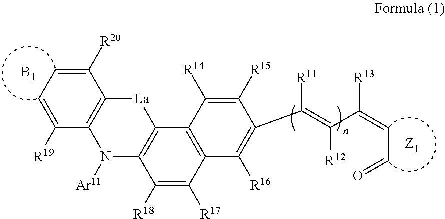

### CROSS-REFERENCE TO RELATED APPLICATIONS

This application is a Continuation of PCT International Application No. PCT/JP2014/058204 filed on Mar. 25, 2014, which claims priority under 35 U.S.C. §119(a) to Japanese Patent Application No. 2013-066496 filed on Mar. 27, 2013 and Japanese Patent Application No. 2013-233105 filed on Nov. 11, 2013. Each of the above applications is hereby expressly incorporated by reference, in its entirety, into the present application.

### BACKGROUND OF THE INVENTION

The present invention relates to a photoelectric conversion element and a method of using the same as well as an optical sensor and an image sensor.

A conventional optical sensor is a device having photodiodes (PDs) formed in a semiconductor substrate made of, for example, silicon (Si) and a planar solid-state image sensor in which PDs are two-dimensionally arranged and signal charges generated in the respective PDs are read out by circuits is widely used as the solid-state image sensor.

The structure in which color filters for transmitting light having specific wavelengths therethrough are disposed on the light incidence surface side of a planar solid-state image sensor is common in order to realize a color solid-state image sensor. At present, a single-plate solid-state image sensor which is widely used in a digital camera or other device and in which color filters for transmitting blue (B) light, green (G) light and red (R) light therethrough are regularly disposed on individual PDs in a two-dimensional array is well known.

Recently, a solid-state image sensor having a configuration in which an organic photoelectric conversion film is formed on a signal readout substrate is under progressive development.

In particular, the responsiveness and the photoelectric conversion efficiency are issues to be solved in solid-state image sensors and photoelectric conversion elements using such an organic photoelectric conversion film.

Under these circumstances, for example, JP 2011-213706 A and JP 2012-77064 A each disclose a photoelectric conversion element containing a photoelectric conversion material having a specific structure.

### SUMMARY OF THE INVENTION

With the demand for improving the performance of image sensors and optical sensors, it is recently required to improve various characteristics such as photoelectric conversion efficiency and responsiveness that are required of photoelectric conversion elements for use in the image sensors and optical sensors.

The inventors of the present invention have prepared photoelectric conversion elements using the compound (12) disclosed in Examples of JP 2011-213706 A and found that the responsiveness and the photoelectric conversion efficiency do not necessarily reach the level nowadays required and further improvement is necessary.

In view of the situation as described above, the present invention aims at providing a photoelectric conversion element exhibiting excellent responsiveness and high photoelectric conversion efficiency.

The present invention also aims at providing a method of using the photoelectric conversion element as well as an optical sensor and an image sensor including the photoelectric conversion element.

The inventors of the present invention have made an intensive study to solve the above problems and as a result found that a photoelectric conversion element exhibiting excellent responsiveness and high photoelectric conversion efficiency is obtained by using a compound (A) represented by formula (1) to be described below as the photoelectric conversion material and the present invention has been thus completed. Accordingly, the inventors of the present invention have found that the problems can be solved by the characteristic features as described below.

(1) A photoelectric conversion element comprising: a conductive film; a photoelectric conversion film containing a photoelectric conversion material; and a transparent conductive film, the conductive film, the photoelectric conversion film and the transparent conductive film being formed in this order, and the photoelectric conversion material containing a compound (A) represented by formula (1) described below.

(2) The photoelectric conversion element according to (1), wherein Z₁ in formula (1) is a ring represented by formula (Z1) described below.

(3) The photoelectric conversion element according to (1) or

(2), wherein Ar¹¹ in formula (1) is an optionally substituted aryl group.

(4) The photoelectric conversion element according to any one of (1) to (3), wherein the compound (A) is a compound (a1) represented by formula (2) described below.

(5) The photoelectric conversion element according to (4), wherein n in formula (2) is 0.

(6) The photoelectric conversion element according to (4) or

(5), wherein La in formula (2) is a group represented by >CR^{1a}R^{1b} (where R^{1a} and R^{1b} each independently represent a hydrogen atom or a hydrocarbon group).

(7) The photoelectric conversion element according to any one of (4) to (6), wherein the compound (a1) is a compound (a2) represented by formula (3) described below.

(8) The photoelectric conversion element according to any one of (1) to (7), wherein the photoelectric conversion film further contains an organic n-type semiconductor.

(9) The photoelectric conversion element according to (8), wherein the organic n-type semiconductor contains a fullerene-based compound selected from the group consisting of fullerenes and fullerene derivatives.

(10) The photoelectric conversion element according to (9), wherein a content ratio of the fullerene-based compound to a sum of the photoelectric conversion material and the fullerene-based compound (film thickness of the fullerene-based compound calculated as a single layer/(film thickness of the photoelectric conversion material calculated as a single layer+film thickness of the fullerene-based compound calculated as a single layer)) is at least 50 vol %.

(11) The photoelectric conversion element according to any one of (1) to (10), wherein a charge blocking layer is provided between the conductive film and the transparent conductive film.

(12) The photoelectric conversion element according to any one of (1) to (11), wherein the photoelectric conversion film is formed by vacuum deposition.

(13) The photoelectric conversion element according to (1) to (12), wherein light is allowed to enter the photoelectric conversion film through the transparent conductive film.

(14) The photoelectric conversion element according to (1) to (13), wherein the transparent conductive film comprises a transparent conductive metal oxide.

(15) An optical sensor comprising the photoelectric conversion element according to any one of (1) to (14).

(16) An image sensor comprising the photoelectric conversion element according to any one of (1) to (14).

(17) A method of using the photoelectric conversion element according to any one of (1) to (14),

wherein the conductive film and the transparent conductive film form an electrode pair and an electric field of 1×10⁻⁴ to 1×10⁷ V/cm is applied across the electrode pair.

As will be described later, the present invention can provide a photoelectric conversion element exhibiting excellent responsiveness and high photoelectric conversion efficiency.

The present invention can also provide a method of using the photoelectric conversion element as well as an optical sensor including the photoelectric conversion element and an image sensor including the photoelectric conversion element.

### BRIEF DESCRIPTION OF THE DRAWINGS

FIGS. 1A and 1B are schematic cross-sectional views each showing an exemplary configuration of a photoelectric conversion element.

FIG. 2 is a schematic cross-sectional view of a one-pixel portion of an image sensor.

FIG. 3 is a ¹H-NMR spectrum of a compound (2).

FIG. 4 is a ¹H-NMR spectrum of a compound (5).

### DETAILED DESCRIPTION OF THE INVENTION

[Photoelectric Conversion Element]

The photoelectric conversion element of the present invention includes a conductive film, a photoelectric conversion film containing a photoelectric conversion material, and a transparent conductive film which are formed in this order, and the photoelectric conversion material contains a compound (A) represented by formula (1) to be described below.

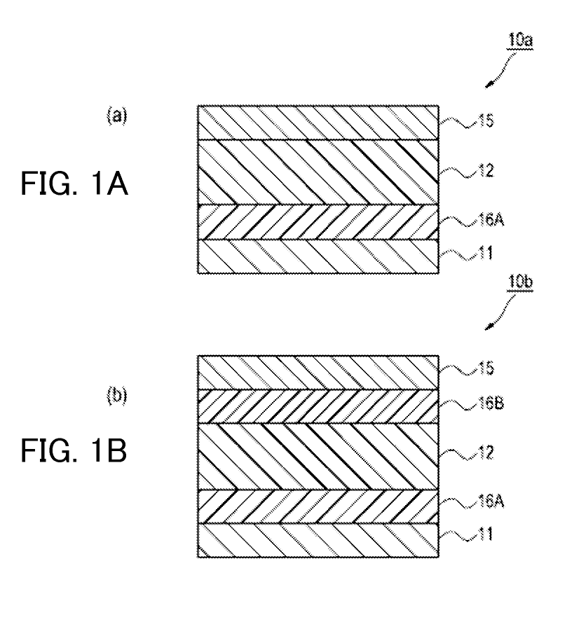

The photoelectric conversion element of the invention is described below with reference to the drawings. FIGS. 1A and 1B are schematic cross-sectional views showing embodiments of the photoelectric conversion element of the invention.

A photoelectric conversion element 10a shown in FIG. 1A has such a configuration that a conductive film serving as a lower electrode (hereinafter also referred to as “lower electrode”) 11, an electron blocking layer 16A formed on the lower electrode 11, a photoelectric conversion film 12 formed on the electron blocking layer 16A, and a transparent conductive film serving as an upper electrode (hereinafter also referred to as “upper electrode”) 15 are laminated in this order.

Another exemplary configuration of the photoelectric conversion element is shown in FIG. 1B. A photoelectric conversion element 10b shown in FIG. 1B has such a configuration that an electron blocking layer 16A, a photoelectric conversion film 12, a hole blocking layer 16B, and an upper electrode 15 are laminated in this order on a lower electrode 11. The electron blocking layers 16A, the photoelectric conversion films 12 and the hole blocking layer 16B in FIGS. 1A and 1B may be formed in reverse order according to the intended use and characteristics.

In the configuration of the photoelectric conversion element 10a (10b), light is preferably allowed to enter the photoelectric conversion film 12 through the transparent conductive film 15.

In the case of using the photoelectric conversion element 10a (10b), an electric field may be applied. In this case, it is preferred to apply an electric field of 1×10⁻⁵ to 1×10⁷ V/cm and more preferably 1×10⁻⁴ to 1×10⁷ V/cm across an electrode pair formed with the conductive film 11 and the transparent conductive film 15. It is preferred to apply an electric field of 1×10⁻⁴ to 1×10⁶ V/cm and more preferably 1×10⁻³ to 5×10⁵ V/cm in terms of performance and power consumption.

With regard to the voltage application method, it is preferred to apply a voltage so that the electron blocking layer 16A side is a cathode and the photoelectric conversion film 12 side is an anode in FIGS. 1A and 1B. A voltage may also be applied by the same method in both a case in which the photoelectric conversion element 10a (10b) is used as an optical sensor and a case in which the photoelectric conversion element 10a (10b) is incorporated in an image sensor.

Embodiments of the respective layers (e.g., the photoelectric conversion film, the lower electrode, the upper electrode, the electron blocking layer, and the hole blocking layer) making up the photoelectric conversion element 10a (10b) are described below in detail.

The photoelectric conversion film is first described below in detail.

[Photoelectric Conversion Film]

The photoelectric conversion film is a film containing the compound (A) represented by formula (1) which will be described later as the photoelectric conversion material.

Since the present invention uses the compound (A) to be described later as the photoelectric conversion material, the resulting photoelectric conversion element is considered to exhibit excellent responsiveness and high photoelectric conversion efficiency.

The reason therefor is not clear but is probably presumed as follows:

As is seen from formula (1) to be described later, the compound (A) has a structure in which a specific arylamine is linked to a ring represented by Z₁ via a linkage moiety having a specific structure (structure having a naphthalene ring).

Since the arylamine shows electron donating properties (donor properties) and the ring represented by Z₁ shows electron accepting properties (acceptor properties), good charge separation occurs within the molecule of the compound (A) through optical absorption.

In addition, since the arylamine having a specific structure (structure in which a 5-membered ring or a 6-membered ring is fused to an aryl group) and the linkage moiety having a specific structure (structure having a naphthalene ring) are taken together to form a ring, the compound (A) has high flatness from the arylamine to the linkage moiety and a broad HOMO distribution and is strong in intermolecular packing. It is considered that consequently intermolecular quick transfer of electrons or holes is made possible, the responsiveness is excellent and the HOMO-LUMO polarization is large, so that the dipole moment in the excited state is increased and a photoelectric conversion element showing high photoelectric conversion efficiency is obtained.

This is also presumed from the fact that, as is seen from Comparative Examples to be described later, desired effects are not obtained in Comparative Example 1-2 in which an arylamine having a specific structure and a linkage moiety are taken together to form a ring but the linkage moiety does not have a naphthalene ring, Comparative Example 1-3 in which a linkage moiety having a naphthalene ring and an arylamine having a specific structure are present but a ring is not formed therebetween, and Comparative Example 1-4 in which a naphthalene ring of a linkage moiety and an arylamine are taken together to form a ring but the arylamine does not have a specific structure.

<Compound (A)>

According to the invention, the compound (A) that may be used as the photoelectric conversion material is represented by formula (1) below.

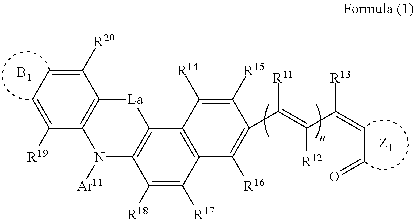

In formula (1), R¹¹ to R¹³ each independently represent a hydrogen atom or a substituent. An example of the substituent includes a substituent W to be described later.

When R¹¹ and R¹² are substituents, alkyl groups having 1 to 10 carbon atoms (in particular methyl group, ethyl group, propyl group, i-propyl group, and t-butyl group), alkenyl groups having 2 to 10 carbon atoms (in particular vinyl group and allyl group), alkoxy groups having 1 to 10 carbon atoms, and alkylthio groups having 1 to 10 carbon atoms are preferable.

R¹³ is preferably a hydrogen atom or an alkyl group having 1 to 10 carbon atoms (in particular a methyl group or an ethyl group).

In formula (1), n is an integer of 0 or more, preferably 0 or more but up to 3, and more preferably 0. If n is increased, a long-wavelength absorption range can be obtained but thermal decomposition temperature is reduced. n is preferably 0 from the viewpoints that proper absorption is shown in the visible range and that thermal decomposition during film formation through vapor deposition is suppressed.

In formula (1), R¹¹ and R¹² or R¹¹ and R¹³ may be taken together to form a ring. When n is 2 or more, a plurality of R¹¹ or R¹² may be taken together to form a ring. An example of the ring that may be formed includes a ring R to be described later. The ring that may be formed may have a substituent. An example of the substituent includes the substituent W to be described later. Some other ring (e.g., the ring R to be described later) may be fused to the ring that may be formed. The ring that may be fused may have a substituent. An example of the substituent includes the substituent W to be described later.

In formula (1), R¹⁴ to R²⁰ each independently represent a hydrogen atom or a substituent. An example of the substituent includes a substituent V to be described later. R¹⁴ to R²⁰ are each preferably a hydrogen atom.

In formula (1), Ar¹¹ represents an optionally substituted aryl group or heteroaryl group. Of these, an optionally substituted aryl group is preferable in terms of heat resistance.

When Ar¹¹ is an aryl group, an aryl group having 6 to 30 carbon atoms is preferable and an aryl group having 6 to 20 carbon atoms is more preferable. Preferable examples of the aryl group include phenyl group, naphthyl group, anthracenyl group, pyrenyl group, fluorenyl group, triphenylenyl group, phenanthrenyl group, methylphenyl group, dimethylphenyl group, biphenyl group (two phenyl groups may be linked together by any linking mode), and terphenyl group (three phenyl groups may be linked together by any linking mode), and phenyl group, naphthyl group and biphenyl group are more preferable.

The aryl group may have a substituent and an example of the substituent of the aryl group includes the substituent V to be described later. A halogen atom, a halogenated alkyl group, an alkyl group having 1 to 4 carbon atoms or an aryl group having 6 to 18 carbon atoms is a preferable substituent of the aryl group.

When Ar¹¹ is a heteroaryl group, a heteroaryl group composed of a 5-, 6- or 7-membered ring or a fused ring thereof is preferable. Exemplary heteroatoms contained in the heteroaryl group include oxygen atom, sulfur atom and nitrogen atom. Specific examples of the ring making up the heteroaryl group include furan ring, thiophene ring, pyrrole ring, pyrroline ring, pyrrolidine ring, oxazole ring, isoxazole ring, thiazole ring, isothiazole ring, imidazole ring, imidazoline ring, imidazolidine ring, pyrazole ring, pyrazoline ring, pyrazolidine ring, triazole ring, furazan ring, tetrazole ring, pyran ring, thiin ring, pyridine ring, piperidine ring, oxazine ring, morpholine ring, thiazine ring, pyridazine ring, pyrimidine ring, pyrazine ring, piperazine ring, triazine ring, benzofuran ring, isobenzofuran ring, benzothiophene ring, indole ring, indoline ring, isoindole ring, benzoxazole ring, benzothiazole ring, indazole ring, benzimidazole ring, quinoline ring, isoquinoline ring, cinnoline ring, phthalazine ring, quinazoline ring, quinoxaline ring, dibenzofuran ring, dibenzothiophene ring, carbazole ring, xanthene ring, acridine ring, phenanthridine ring, phenanthroline ring, phenazine ring, phenoxazine ring, thianthrene ring, indolizine ring, quinolizine ring, quinuclidine ring, naphthyridine ring, purine ring and pteridine ring.

An example of the substituent of the heteroaryl group includes the substituent V to be described later.

The substituent on Ar¹¹ may directly form a single bond with R¹⁸ or R¹⁹. Alternatively, Ar¹¹ may be taken together with R¹⁸ or R¹⁹ via a divalent organic group to form a ring.

Examples of the divalent organic group include an optionally substituted divalent aliphatic hydrocarbon group (e.g., an alkylene group preferably having 1 to 8 carbon atoms), an optionally substituted divalent aromatic hydrocarbon group (e.g., an arylene group preferably having 6 to 12 carbon atoms), —O—, —S—, —SO₂—, —NR— (R: the substituent V to be described later), —SiR¹R²— (R¹ and R²: the substituent V to be described later), —CO—, —NH—, —COO—, —CONH—, and combination groups thereof (e.g., an alkyleneoxy group, an alkyleneoxycarbonyl group and an alkylenecarbonyloxy group).

In formula (1), La represents a group selected from the group consisting of >CR^{1a}R^{1b}, >NR^{1c}, an alkenylene group optionally substituted with, for example, the substituent V to be described later, —O—, —S—, and >SiR^{1d}R^{1e}. R^{1a}, R^{1b}, R^{1c}, R^{1d} and R^{1e} each independently represent a hydrogen atom or a substituent (e.g., a hydrocarbon group). An example of the substituent includes the substituent V to be described later. Above all, alkyl groups having 1 to 10 carbon atoms (in particular methyl group and ethyl group) are preferable. When La is an optionally substituted alkenylene group, some other ring (e.g., the ring R to be described later) may be fused to the ring formed by La. The ring that may be fused may have a substituent. An example of the substituent includes the substituent V to be described later.

La is preferably a group represented by >CR^{1a}R^{1b}.

Z₁ is a ring containing at least two carbon atoms and represents a 5-membered ring, a 6-membered ring or a fused ring containing at least one of a 5-membered ring and a 6-membered ring.

A ring which is generally used as an acidic nucleus in a merocyanine dye is preferable as such a ring, and specific examples thereof include the followings:

(a) 1,3-Dicarbonyl nucleus: for example, 1,3-indandione nucleus, 1,3-cyclohexanedione, 5,5-dimethyl-1,3-cyclohexanedione, and 1,3-dioxane-4,6-dione.

(b) Pyrazolinone nucleus: for example, 1-phenyl-2-pyrazolin-5-one, 3-methyl-1-phenyl-2-pyrazolin-5-one, and 1-(2-benzothiazolyl)-3-methyl-2-pyrazolin-5-one.

(c) Isoxazolinone nucleus: for example, 3-phenyl-2-isoxazolin-5-one, and 3-methyl-2-isoxazolin-5-one.

(d) Oxindole nucleus: for example, 1-alkyl-2,3-dihydro-2-oxindole.

(e) 2,4,6-Trioxohexahydropyrimidine nucleus: for example, barbituric acid or 2-thiobarbituric acid and derivatives thereof. Exemplary derivatives include 1-alkyl derivatives such as 1-methyl and 1-ethyl; 1,3-dialkyl derivatives such as 1,3-dimethyl, 1,3-diethyl, and 1,3-dibutyl; 1,3-diaryl derivatives such as 1,3-diphenyl, 1,3-di(p-chlorophenyl), and 1,3-di(p-ethoxycarbonylphenyl); 1-alkyl-1-aryl derivatives such as 1-ethyl-3-phenyl; and 1,3-diheteroaryl derivatives such as 1,3-di(2-pyridyl).

(f) 2-Thio-2,4-thiazolidinedione nucleus: for example, rhodanine and derivatives thereof. Exemplary derivatives include 3-alkylrhodanines such as 3-methylrhodanine, 3-ethylrhodanine, and 3-allylrhodanine; 3-arylrhodanines such as 3-phenylrhodanine; and 3-heteroarylrhodanines such as 3-(2-pyridyl)rhodanine.

(g) 2-Thio-2,4-oxazolidinedione (2-thio-2,4-(3H,5H)-oxazoledione) nucleus: for example, 3-ethyl-2-thio-2,4-oxazolidinedione.

(h) Thianaphthenone nucleus: for example, 3(2H)-thianaphthenone-1,1-dioxide.

(i) 2-Thio-2,5-thiazolidinedione nucleus: for example, 3-ethyl-2-thio-2,5-thiazolidinedione.

(j) 2,4-Thiazolidinedione nucleus: for example, 2,4-thiazolidinedione, 3-ethyl-2,4-thiazolidinedione, and 3-phenyl-2,4-thiazolidinedione.

(k) Thiazolin-4-one nucleus: for example, 4-thiazolinone, and 2-ethyl-4-thiazolinone.

(l) 2,4-Imidazolidinedione (hydantoin) nucleus: for example, 2,4-imidazolidinedione, and 3-ethyl-2,4-imidazolidinedione.

(m) 2-Thio-2,4-imidazolidinedione (2-thiohydantoin) nucleus: for example, 2-thio-2,4-imidazolidinedione, and 3-ethyl-2-thio-2,4-imidazolidinedione.

(n) Imidazolin-5-one nucleus: for example, 2-propylmercapto-2-imidazolin-5-one.

(o) 3,5-Pyrazolidinedione nucleus: for example, 1,2-diphenyl-3,5-pyrazolidinedione, and 1,2-dimethyl-3,5-pyrazolidinedione.

(p) Benzothiophen-3(2H)-one nucleus: for example, benzothiophen-3(2H)-one, oxobenzothiophen-3(2H)-one, and dioxobenzothiophen-3 (2H)-one.

(q) Indanone nucleus: for example, 1-indanone, 3-phenyl-1-indanone, 3-methyl-1-indanone, 3,3-diphenyl-1-indanone, and 3,3-dimethyl-1-indanone.

(r) Benzofuran-3-(2H)-one nucleus: for example, benzofuran-3-(2H)-one.

(s) 2,2-dihydrophenalene-1,3-dione nucleus etc.

These may further have a substituent. Furthermore, some other ring may be fused.

Z₁ as described above may have a substituent. An example of the substituent includes the substituent V to be described later.

Z₁ as described above is preferably a group represented by formula (Z1) shown below because various characteristics of the photoelectric conversion element such as the responsiveness, the sensitivity and the heat resistance are more excellent.

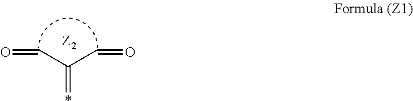

In formula (Z1), Z₂ is a ring containing at least three carbon atoms and represents a 5-membered ring, a 6-membered ring or a fused ring containing at least one of a 5-membered ring and a 6-membered ring. * represents a bonding position with a carbon atom to which R¹³ in formula (1) above is attached.

In formula (1) above, B₁ represents an optionally substituted 5- or 6-membered ring. More specifically, B₁ is a 5- or 6-membered ring selected from among aromatic hydrocarbon rings, aromatic heterocyclic rings, non-aromatic hydrocarbon rings and non-aromatic heterocyclic rings. Of these, an aromatic hydrocarbon ring or aromatic heterocyclic ring is preferable and an aromatic hydrocarbon ring is more preferable in terms of more excellent responsiveness and higher photoelectric conversion efficiency.

B₁ may further have a fused ring structure. In other words, some other ring (e.g., the ring R to be described later) may be fused. The ring that may be fused may have a substituent. An example of the substituent includes the substituent V to be described later.

A preferred embodiment of the compound (A) is a compound (a1) represented by formula (2) below.

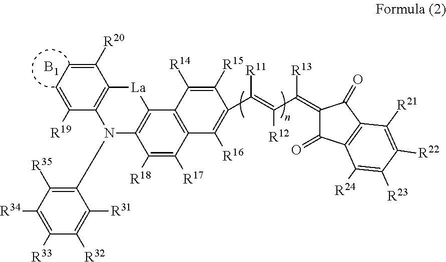

In formula (2) above, the definitions, specific examples and preferred embodiments of R¹¹ to R¹³ are the same as those in formula (1) described above.

In formula (2) above, the definition and preferred embodiment of n are the same as those in formula (1) described above.

In formula (2) above, the definitions, specific examples and preferred embodiments of R¹⁴ to R²⁰ are the same as those in formula (1) described above.

In formula (2) above, R²¹ to R²⁴ each independently represent a hydrogen atom or a substituent. An example of the substituent includes the substituent V to be described later. R²¹ to R²⁴ are each preferably a hydrogen atom. R²¹ and R²², R²² and R²³ or R²³ and R²⁴ may be taken together to form a ring. An example of the ring that may be formed includes the ring R to be described later. The ring that may be formed may have a substituent. An example of the substituent includes the substituent V to be described later.

In formula (2) above, R³¹ to R³⁵ each independently represent a hydrogen atom or a substituent. An example of the substituent includes the substituent V to be described later. R³¹ to R³⁵ are each preferably a hydrogen atom, a halogen atom, an alkyl group having 1 to 10 carbon atoms or an aryl group having 6 to 12 carbon atoms. R³¹ and R³², R³² and R³³, R³³ and R³⁴ or R³⁴ and R³⁵ may be taken together to form a ring. An example of the ring that may be formed includes the ring R to be described later. The ring that may be formed may have a substituent. An example of the substituent includes the substituent V to be described later.

In formula (2) above, the definition, specific examples and preferred embodiment of La are the same as those in formula (1) described above.

In formula (2) above, the definition, specific examples and preferred embodiment of B₁ are the same as those in formula (1) described above.

A preferred embodiment of the compound (a1) is a compound (a3) represented by formula (3) below.

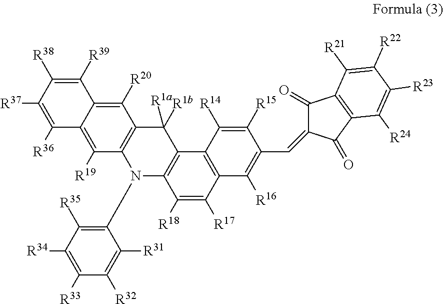

In formula (3) above, the definitions, specific examples and preferred embodiments of R¹⁴ to R²⁰ are the same as those in formula (1) described above.

In formula (3) above, the definitions, specific examples and preferred embodiments of R²¹ to R²⁴ are the same as those in formula (2) described above.

In formula (3) above, the definitions, specific examples and preferred embodiments of R³¹ to R³⁵ are the same as those in formula (2) described above.

In formula (3) above, R³⁶ to R³⁹ each independently represent a hydrogen atom or a substituent. An example of the substituent includes the substituent V to be described later. R³⁶ to R³⁹ are each preferably a hydrogen atom. R³⁶ and R³⁷, R³⁷ and R³⁸ or R³⁸ and R³⁹ may be taken together to form a ring. An example of the ring that may be formed includes the ring R to be described later. The ring that may be formed may have a substituent. An example of the substituent includes the substituent V to be described later.

In formula (3) above, R^{1a} and R^{1b} each independently represent a hydrogen atom or a substituent. An example of the substituent includes the substituent V to be described later. R^{1a} and R^{1b} are each preferably an alkyl group having 1 to 10 carbon atoms (in particular a methyl group or an ethyl group), an aryl group having 6 to 12 carbon atoms (in particular a phenyl group) and more preferably a methyl group. R^{1a} and R^{1b} may be taken together to form a ring. An example thereof includes a cycloalkyl group.

(Substituent W)

The substituent W in the specification is now described.

Examples of the substituent W include halogen atoms, alkyl groups (including cycloalkyl groups, bicycloalkyl groups and tricycloalkyl groups), alkenyl groups (including cycloalkenyl groups and bicycloalkenyl groups), alkynyl groups, aryl groups, heterocyclic groups, cyano group, hydroxy group, nitro group, carboxy group, alkoxy groups, aryloxy groups, silyloxy group, heterocyclic oxy groups, acyloxy groups, carbamoyloxy group, alkoxycarbonyloxy groups, aryloxycarbonyloxy groups, amino groups (including anilino group), ammonio group, acylamino groups, aminocarbonylamino groups, alkoxycarbonylamino groups, aryloxycarbonylamino groups, sulfamoylamino groups, alkyl or arylsulfonylamino groups, mercapto group, alkylthio groups, arylthio groups, heterocyclic thio groups, sulfamoyl group, sulfo group, alkyl or arylsulfinyl groups, alkyl or arylsulfonyl groups, acyl groups, aryloxycarbonyl groups, alkoxycarbonyl groups, carbamoyl group, aryl or heterocyclic azo groups, imido group, phosphino group, phosphinyl group, phosphinyloxy group, phosphinylamino groups, phosphono group, silyl group, hydrazino group, ureido group, boronic acid group (—B(OH)₂), phosphate group (—OPO(OH)₂), sulfate group (—OSO₃H) and other known substituents.

The substituent W is described in detail in paragraph of JP 2007-234651 A.

(Substituent V)

The substituent V in the specification is now described.

Examples of the substituent V include halogen atoms, alkyl groups (including cycloalkyl groups, bicycloalkyl groups and tricycloalkyl groups), alkenyl groups (including cycloalkenyl groups and bicycloalkenyl groups), alkynyl groups, aryl groups, heterocyclic groups, cyano group, nitro group, carboxy group, amino groups (including anilino group), ammonio group, acyl groups, carbamoyl group, aryl or heterocyclic azo groups, imido group, phosphino group, phosphinyl group, phosphinyloxy group, phosphinylamino groups, phosphono group, hydrazino group, ureido group, and boronic acid group (—B(OH)₂).

(Ring R)

The ring R in the specification is now described.

Exemplary rings R include aromatic hydrocarbon rings, aromatic heterocyclic rings, non-aromatic hydrocarbon rings, non-aromatic heterocyclic rings, and fused polycyclic rings formed by combinations thereof. More specific examples of the ring include benzene ring, naphthalene ring, anthracene ring, phenanthrene ring, fluorene ring, triphenylene ring, naphthacene ring, biphenyl ring, pyrrole ring, furan ring, thiophene ring, imidazole ring, oxazole ring, thiazole ring, pyridine ring, pyrazine ring, pyrimidine ring, pyridazine ring, indolizine ring, indole ring, benzofuran ring, benzothiophene ring, isobenzofuran ring, quinolizine ring, quinoline ring, phthalazine ring, naphthyridine ring, quinoxaline ring, quinoxazoline ring, isoquinoline ring, carbazole ring, phenanthridine ring, acridine ring, phenanthroline ring, thianthrene ring, chromene ring, xanthene ring, phenoxathiin ring, phenothiazine ring, phenazine ring, cyclopentane ring, cyclohexane ring, pyrrolidine ring, piperidine ring, tetrahydrofuran ring, tetrahydropyran ring, tetrahydrothiophene ring and tetrahydrothiopyran ring.

The compound (A) can be manufactured by implementing a partially modified known method. Specific examples of the compound represented by the compound (A) are shown below but the invention is not limited thereto.

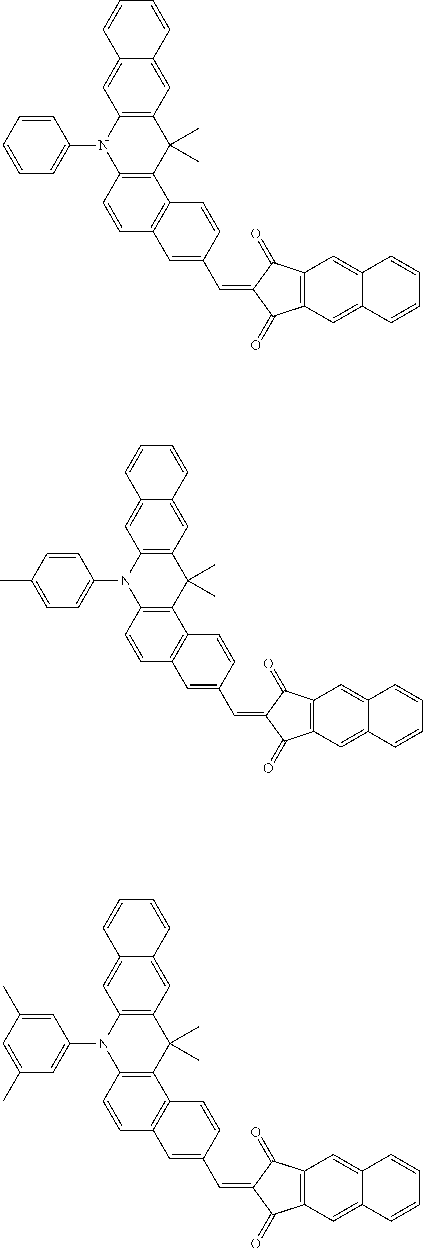 [SMILES: CC1(C)c2cc3ccccc3cc2N(c2ccccc2)c2ccc3cc(C=C4C(=O)c5cc6ccccc6cc5C4=O)ccc3c21 ; Cc1ccc(N2c3cc4ccccc4cc3C(C)(C)c3c2ccc2cc(C=C4C(=O)c5cc6ccccc6cc5C4=O)ccc32)cc1 ; Cc1cc(C)cc(N2c3cc4ccccc4cc3C(C)(C)c3c2ccc2cc(C=C4C(=O)c5cc6ccccc6cc5C4=O)ccc32)c1]

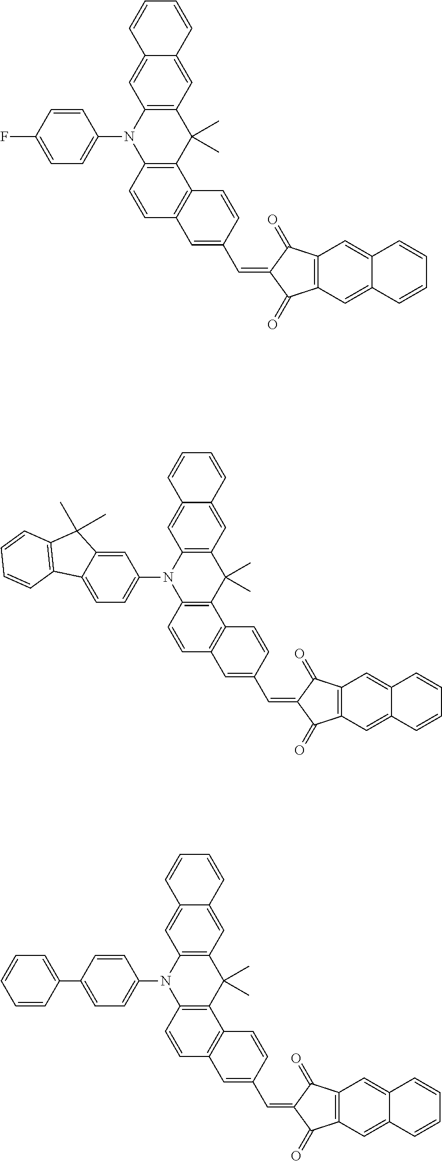 [SMILES: CC1(C)c2cc3ccccc3cc2N(c2ccc(F)cc2)c2ccc3cc(C=C4C(=O)c5cc6ccccc6cc5C4=O)ccc3c21 ; CC1(C)c2ccccc2-c2ccc(N3c4cc5ccccc5cc4C(C)(C)c4c3ccc3cc(C=C5C(=O)c6cc7ccccc7cc6C5=O)ccc43)cc21 ; CC1(C)c2cc3ccccc3cc2N(c2ccc(-c3ccccc3)cc2)c2ccc3cc(C=C4C(=O)c5cc6ccccc6cc5C4=O)ccc3c21]

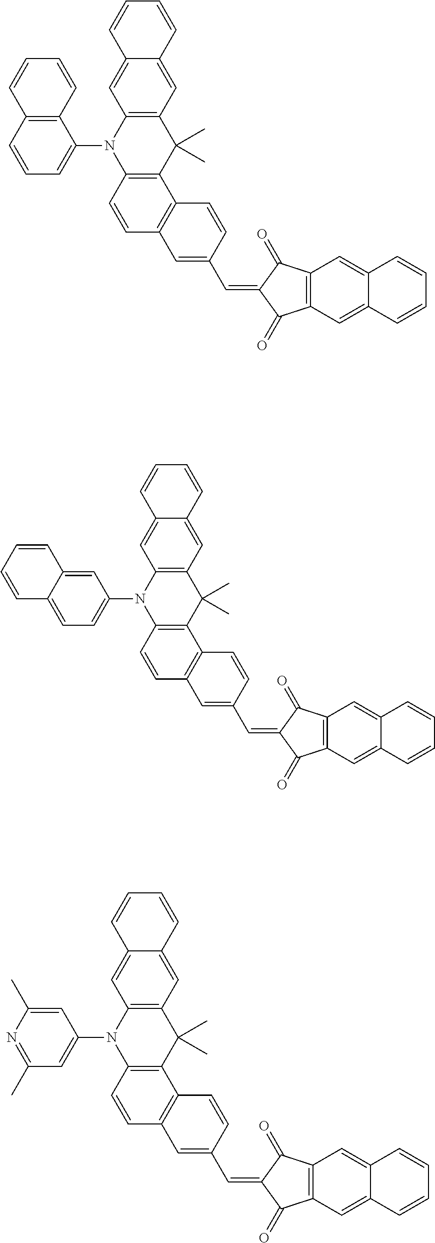 [SMILES: CC1(C)c2cc3ccccc3cc2N(c2cccc3ccccc23)c2ccc3cc(C=C4C(=O)c5cc6ccccc6cc5C4=O)ccc3c21 ; CC1(C)c2cc3ccccc3cc2N(c2ccc3ccccc3c2)c2ccc3cc(C=C4C(=O)c5cc6ccccc6cc5C4=O)ccc3c21 ; Cc1cc(N2c3cc4ccccc4cc3C(C)(C)c3c2ccc2cc(C=C4C(=O)c5cc6ccccc6cc5C4=O)ccc32)cc(C)n1]

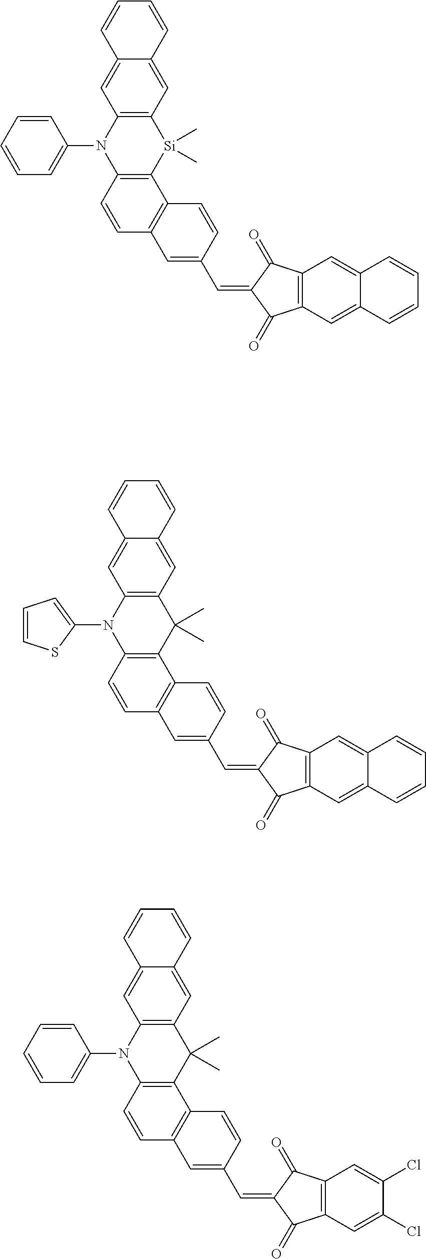 [SMILES: C[Si]1(C)c2cc3ccccc3cc2N(c2ccccc2)c2ccc3cc(C=C4C(=O)c5cc6ccccc6cc5C4=O)ccc3c21 ; CC1(C)c2cc3ccccc3cc2N(c2cccs2)c2ccc3cc(C=C4C(=O)c5cc6ccccc6cc5C4=O)ccc3c21 ; CC1(C)c2cc3ccccc3cc2N(c2ccccc2)c2ccc3cc(C=C4C(=O)c5cc(Cl)c(Cl)cc5C4=O)ccc3c21]

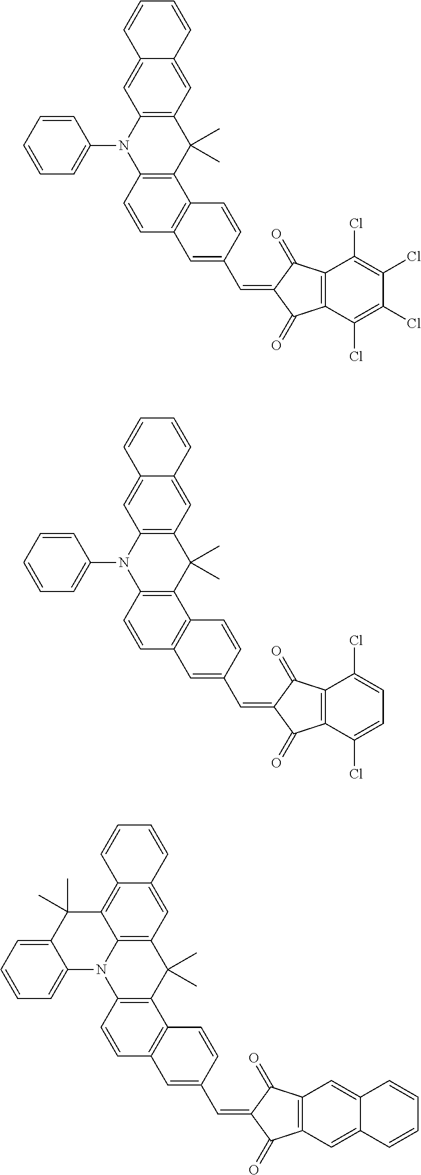 [SMILES: CC1(C)c2cc3ccccc3cc2N(c2ccccc2)c2ccc3cc(C=C4C(=O)c5c(Cl)c(Cl)c(Cl)c(Cl)c5C4=O)ccc3c21 ; CC1(C)c2cc3ccccc3cc2N(c2ccccc2)c2ccc3cc(C=C4C(=O)c5c(Cl)ccc(Cl)c5C4=O)ccc3c21 ; CC1(C)c2cc3ccccc3c3c2N(c2ccccc2C3(C)C)c2ccc3cc(C=C4C(=O)c5cc6ccccc6cc5C4=O)ccc3c21]

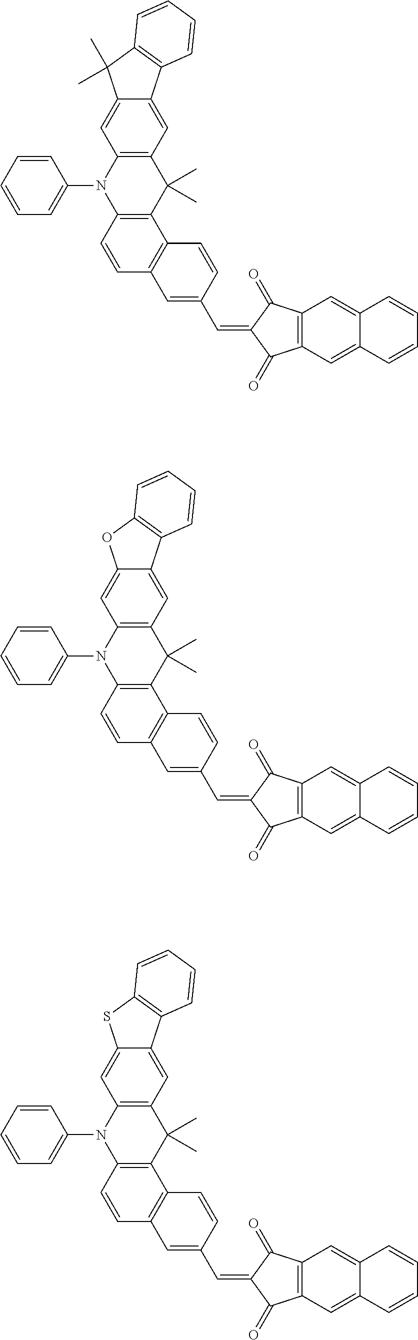 [SMILES: CC1(C)c2ccccc2-c2cc3c(cc21)N(c1ccccc1)c1ccc2cc(C=C4C(=O)c5cc6ccccc6cc5C4=O)ccc2c1C3(C)C ; CC1(C)c2cc3c(cc2N(c2ccccc2)c2ccc4cc(C=C5C(=O)c6cc7ccccc7cc6C5=O)ccc4c21)oc1ccccc13 ; CC1(C)c2cc3c(cc2N(c2ccccc2)c2ccc4cc(C=C5C(=O)c6cc7ccccc7cc6C5=O)ccc4c21)sc1ccccc13]

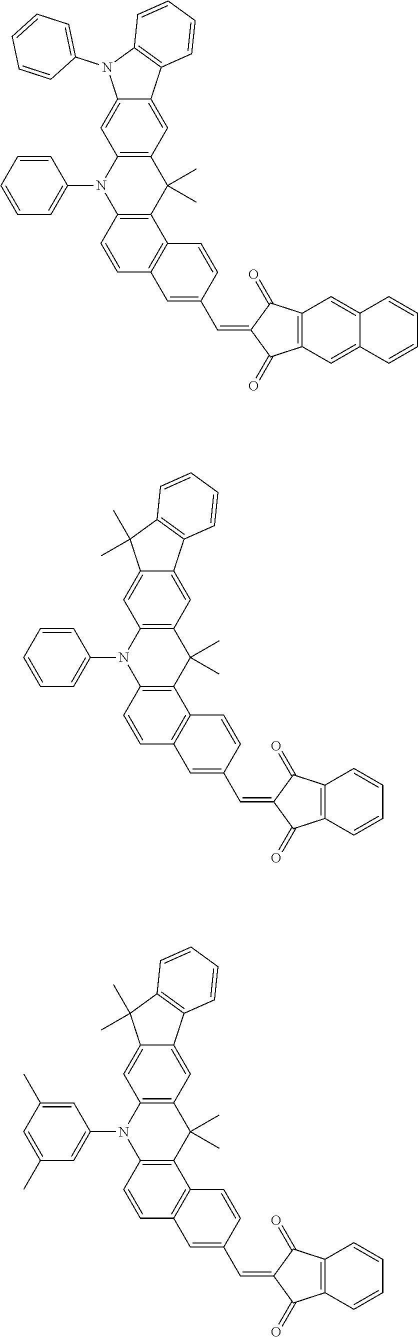 [SMILES: CC1(C)c2cc3c4ccccc4n(-c4ccccc4)c3cc2N(c2ccccc2)c2ccc3cc(C=C4C(=O)c5cc6ccccc6cc5C4=O)ccc3c21 ; CC1(C)c2ccccc2-c2cc3c(cc21)N(c1ccccc1)c1ccc2cc(C=C4C(=O)c5ccccc5C4=O)ccc2c1C3(C)C ; Cc1cc(C)cc(N2c3cc4c(cc3C(C)(C)c3c2ccc2cc(C=C5C(=O)c6ccccc6C5=O)ccc32)-c2ccccc2C4(C)C)c1]

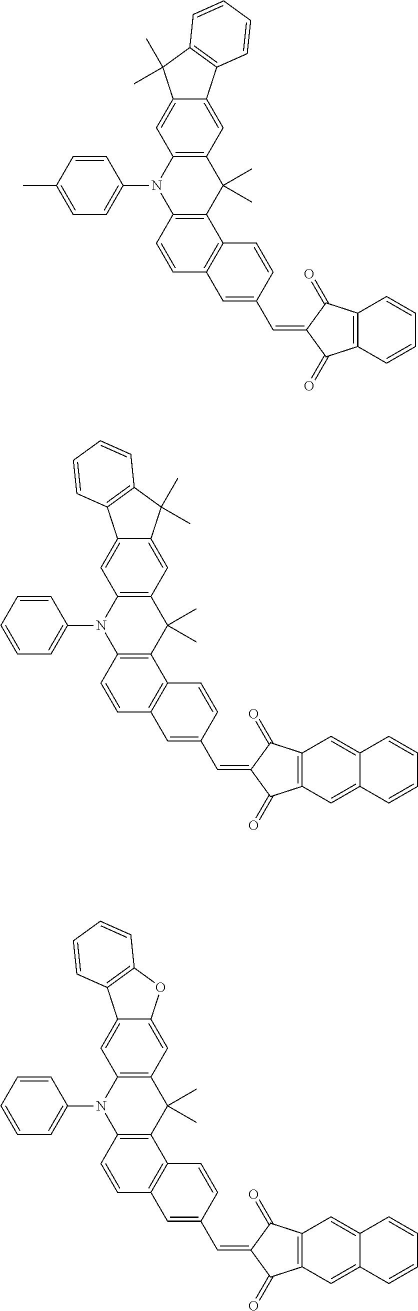 [SMILES: Cc1ccc(N2c3cc4c(cc3C(C)(C)c3c2ccc2cc(C=C5C(=O)c6ccccc6C5=O)ccc32)-c2ccccc2C4(C)C)cc1 ; CC1(C)c2ccccc2-c2cc3c(cc21)C(C)(C)c1c(ccc2cc(C=C4C(=O)c5cc6ccccc6cc5C4=O)ccc12)N3c1ccccc1 ; CC1(C)c2cc3oc4ccccc4c3cc2N(c2ccccc2)c2ccc3cc(C=C4C(=O)c5cc6ccccc6cc5C4=O)ccc3c21]

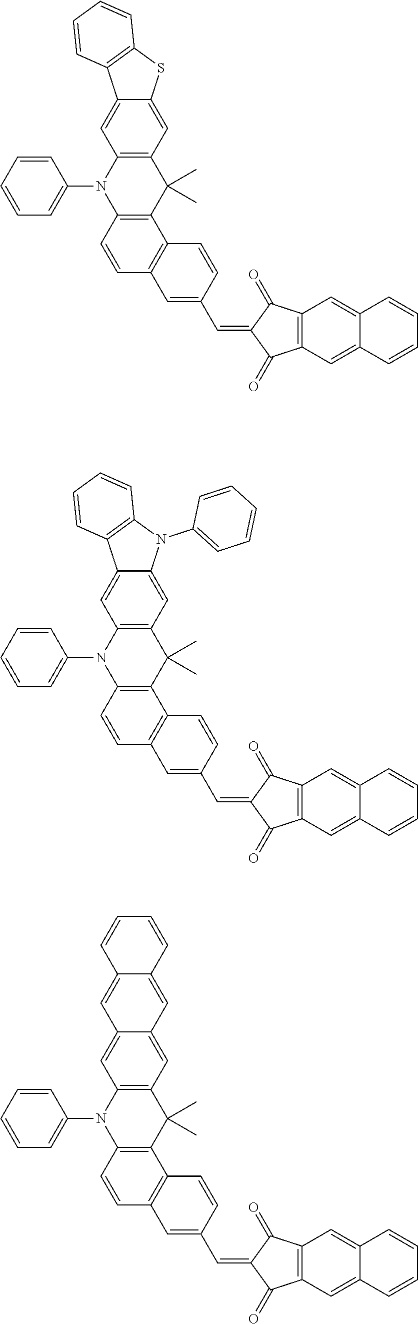 [SMILES: CC1(C)c2cc3sc4ccccc4c3cc2N(c2ccccc2)c2ccc3cc(C=C4C(=O)c5cc6ccccc6cc5C4=O)ccc3c21 ; CC1(C)c2cc3c(cc2N(c2ccccc2)c2ccc4cc(C=C5C(=O)c6cc7ccccc7cc6C5=O)ccc4c21)c1ccccc1n3-c1ccccc1 ; CC1(C)c2cc3cc4ccccc4cc3cc2N(c2ccccc2)c2ccc3cc(C=C4C(=O)c5cc6ccccc6cc5C4=O)ccc3c21]

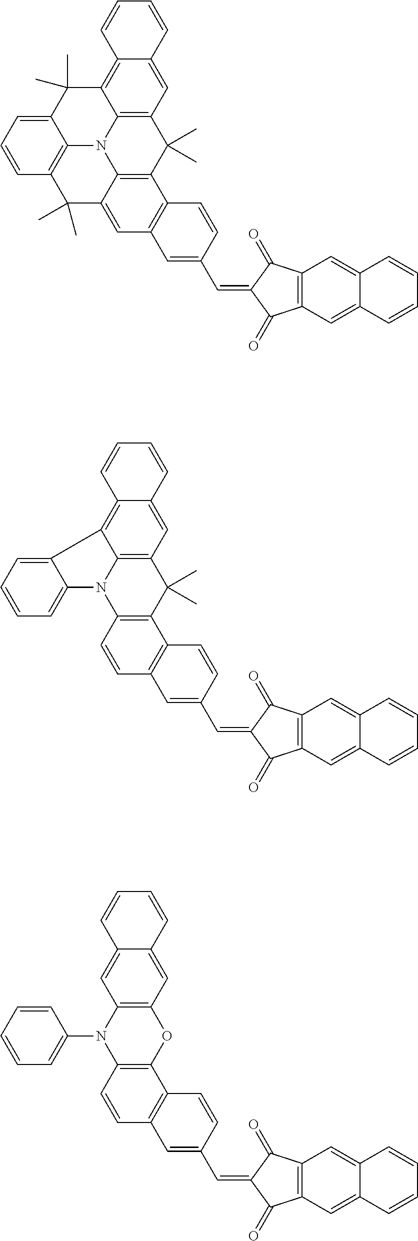 [SMILES: CC1(C)c2cccc3c2N2c4c(cc5ccccc5c4C3(C)C)C(C)(C)c3c2c1cc1cc(C=C2C(=O)c4cc5ccccc5cc4C2=O)ccc31 ; CC1(C)c2c(ccc3cc(C=C4C(=O)c5cc6ccccc6cc5C4=O)ccc23)-n2c3ccccc3c3c4ccccc4cc1c32 ; O=C1C(=Cc2ccc3c4c(ccc3c2)N(c2ccccc2)c2cc3ccccc3cc2O4)C(=O)c2cc3ccccc3cc21]

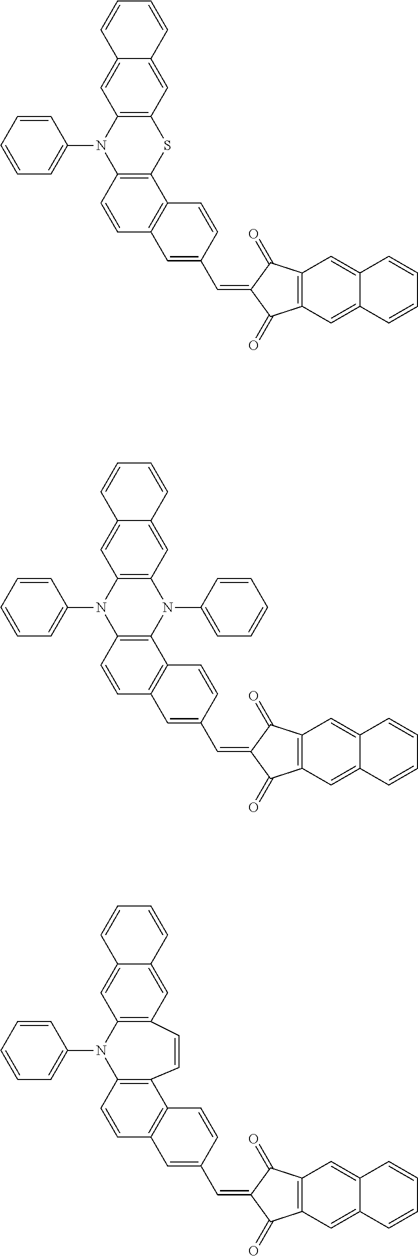 [SMILES: O=C1C(=Cc2ccc3c4c(ccc3c2)N(c2ccccc2)c2cc3ccccc3cc2S4)C(=O)c2cc3ccccc3cc21 ; O=C1C(=Cc2ccc3c4c(ccc3c2)N(c2ccccc2)c2cc3ccccc3cc2N4c2ccccc2)C(=O)c2cc3ccccc3cc21 ; O=C1C(=Cc2ccc3c4c(ccc3c2)N(c2ccccc2)c2cc3ccccc3cc2C=C4)C(=O)c2cc3ccccc3cc21]

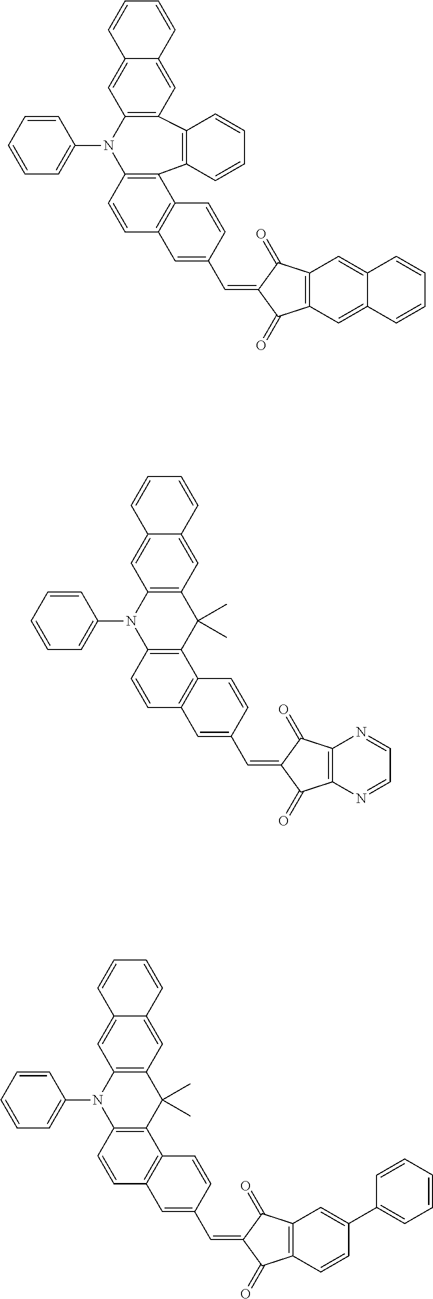 [SMILES: O=C1C(=Cc2ccc3c4c(ccc3c2)N(c2ccccc2)c2cc3ccccc3cc2-c2ccccc2-4)C(=O)c2cc3ccccc3cc21 ; CC1(C)c2cc3ccccc3cc2N(c2ccccc2)c2ccc3cc(C=C4C(=O)c5nccnc5C4=O)ccc3c21 ; CC1(C)c2cc3ccccc3cc2N(c2ccccc2)c2ccc3cc(/C=C4/C(=O)c5ccc(-c6ccccc6)cc5C4=O)ccc3c21]

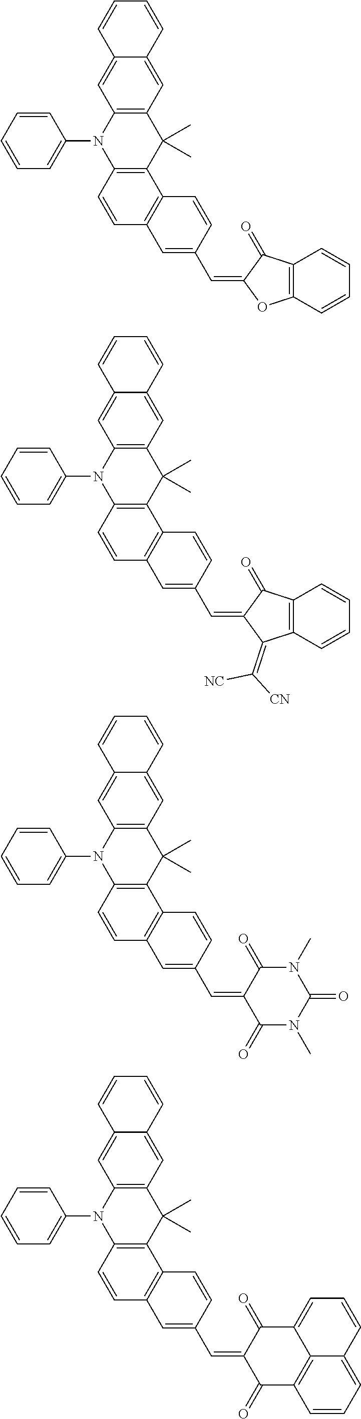 [SMILES: CC1(C)c2cc3ccccc3cc2N(c2ccccc2)c2ccc3cc(/C=C4/Oc5ccccc5C4=O)ccc3c21 ; CC1(C)c2cc3ccccc3cc2N(c2ccccc2)c2ccc3cc(/C=C4\C(=O)c5ccccc5C4=C(C#N)C#N)ccc3c21 ; CN1C(=O)C(=Cc2ccc3c4c(ccc3c2)N(c2ccccc2)c2cc3ccccc3cc2C4(C)C)C(=O)N(C)C1=O ; CC1(C)c2cc3ccccc3cc2N(c2ccccc2)c2ccc3cc(C=c4c(=O)c5cccc6cccc(c4=O)c65)ccc3c21]

The ionization potential (hereinafter sometimes abbreviated as IP) of the compound (A) is preferably up to 6.0 eV, more preferably up to 5.8 eV, and most preferably up to 5.6 eV. The ionization potential is preferably within the above-defined range because in a case where an electrode and another material exist, electron transfer between the electrode and the material is carried out with a small electrical resistance. IP can be determined using AC-2 manufactured by Riken Keiki Co., Ltd.

The compound (A) preferably has absorption maximum at 400 nm or more but less than 720 nm in the UV-visible absorption spectrum. The peak wavelength of the absorption spectrum (absorption maximum wavelength) is preferably 450 nm or more but up to 700 nm, more preferably 480 nm or more but up to 700 nm and even more preferably 510 nm or more but up to 680 nm in terms of wide absorption of light in the visible region.

A solution of the compound (A) in chloroform can be used to measure the absorption maximum wavelength of the compound (A), for example, in UV-2550 manufactured by Shimadzu Corporation. The chloroform solution preferably has a concentration of 5×10⁻⁵ to 1×10⁻⁷ mol/L, more preferably 3×10⁻⁵ to 2×10⁻⁶ mol/L and most preferably 2×10⁻⁵ to 5×10⁻⁶ mol/L.

It is preferable for the compound (A) to have absorption maximum at 400 nm or more but less than 720 nm in the UV-visible absorption spectrum and to have a molar absorbance coefficient of 10,000 mol⁻¹·L·cm⁻¹ or more at the absorption maximum wavelength. A material having a high molar absorbance coefficient is preferably used in order to reduce the thickness of the photoelectric conversion film and obtain an element having high charge collection efficiency and high sensitivity characteristics. The molar absorbance coefficient of the compound (A) is preferably 10,000 mol⁻¹·L·cm⁻¹ or more, more preferably 30,000 mol⁻¹·L·cm⁻¹ or more, and most preferably 50,000 mol⁻¹·L·cm⁻¹ or more. The molar absorbance coefficient of the compound (A) is measured with a chloroform solution.

The larger the difference between the melting point and the deposition temperature (melting point−deposition temperature) is, the less the compound (A) is likely to decompose upon vapor deposition and the deposition rate can be increased by applying a high temperature, which is preferable. The difference between the melting point and the deposition temperature (melting point−deposition temperature) is preferably 40° C. or more, more preferably 50° C. or more, and even more preferably 60° C. or more.

The melting point of the compound (A) is preferably 240° C. or more, more preferably 280° C. or more, and even more preferably 300° C. or more. A melting point of 300° C. or more is preferable because the compound (A) is less likely to melt before vapor deposition at a melting point of 300° C. or more to allow stable film deposition, and in addition, decomposed matter of the compound is comparatively less likely to be formed to minimize the reduction of the photoelectric conversion performance.

The compound is heated in a crucible at a vacuum degree of up to 4×10⁻⁴ Pa and the temperature at which the deposition rate reached 0.4 A/s (0.4×10⁻¹⁰ m/s) is deemed as the vapor temperature of the compound.

The compound (A) preferably has a glass transition point (Tg) of 95° C. or more, more preferably 110° C. or more, even more preferably 135° C. or more, still even more preferably 150° C. or more, and most preferably 160° C. or more. A higher glass transition point is preferable because the heat resistance of the photoelectric conversion element is improved.

The compound (A) preferably has a molecular weight of 300 to 1,500, more preferably 400 to 1,000 and most preferably 500 to 900. Since the deposition temperature can be lowered by reducing the molecular weight, thermal decomposition of the compound upon vapor deposition can be further prevented from occurring. It is also possible to suppress energy necessary for vapor deposition by shortening the deposition time. The deposition temperature of the compound (A) is preferably 400° C. or less, more preferably 380° C. or less, even more preferably 360° C. or less, and most preferably 340° C. or less.

The compound (A) is desirably purified by sublimation before preparing a photoelectric conversion element or an image sensor. Impurities contained before sublimation and residual solvents can be removed by purification through sublimation. As a result, the performance of the photoelectric conversion element and the image sensor can be stabilized. In addition, the deposition rate is easily kept constant.

The compound (A) before purification through sublimation preferably has a purity as measured by HPLC (high-performance liquid chromatography) of at least 99%, more preferably at least 99.5%, and even more preferably at least 99.9%. Furthermore, residual solvents including a reaction solvent and a purification solvent used in the steps up to the formation of the compound (A) are preferably contained in an amount of up to 3%, more preferably up to 1%, even more preferably up to 0.5%, and most preferably up to the detection limit. ¹H-NMR measurement, gas chromatography measurement, Karl Fischer measurement and the like are used to measure the amount of residual solvents contained, inclusive of moisture. Thermal decomposition during purification through sublimation can be suppressed by increasing the purity while reducing the residual solvents.

The compound (A) is particularly useful as a material of the photoelectric conversion film for use in an image sensor, an optical sensor or a photoelectric cell. The compound (A) usually functions as an organic p-type semiconductor (compound) in the photoelectric conversion film. The compound (A) may also be used in other applications such as a coloring material, a liquid crystal material, an organic semiconductor material, an organic electroluminescent element material, a charge transport material, a pharmaceutical material and a fluorescent diagnostic agent material.

<Other Materials>

The photoelectric conversion film may further contain an organic p-type semiconductor (compound) or an organic n-type semiconductor (compound) as the photoelectric conversion material.

The organic p-type semiconductor (compound) is a donor organic semiconductor (compound) mainly typified by a hole transport organic compound and refers to an organic compound having electron donating properties. More specifically, when two organic materials are used in contact with each other, an organic compound having a smaller ionization potential is the organic p-type semiconductor. Therefore, any organic compound can be used as the donor organic compound if it is an electron donating organic compound. For example, a triarylamine compound, a benzidine compound, a pyrazoline compound, a styrylamine compound, a hydrazone compound, a triphenylmethane compound and a carbazole compound can be used.

The organic n-type semiconductor (compound) is an acceptor organic semiconductor mainly typified by an electron transport organic compound and refers to an organic compound having electron accepting properties. More specifically, when two organic compounds are used in contact with each other, an organic compound having a larger electron affinity is the organic n-type semiconductor. Therefore, any organic compound can be used as the acceptor organic compound if it is an electron accepting organic compound. Preferred examples include a fullerene-based compound (a fullerene or a fullerene derivative) selected from the group consisting of fullerenes and fullerene derivatives, condensed aromatic carbocyclic compounds (naphthalene derivatives, anthracene derivatives, phenanthrene derivatives, tetracene derivatives, pyrene derivatives, perylene derivatives, and fluoranthene derivatives), heterocyclic compounds containing nitrogen atom, oxygen atom or sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyraridine, pyrrolopyridine, thiadiazolopyridine, dibenzazepine, and tribenzazepine), polyarylene compounds, fluorene compounds, cyclopentadiene compounds, silyl compounds, and metal complexes having a nitrogen-containing heterocyclic compound as a ligand.

The organic n-type semiconductor (compound) is preferably a fullerene-based compound selected from the group consisting of fullerenes and fullerene derivatives. Fullerenes include fullerene C₆₀, fullerene C₇₀, fullerene C₇₆, fullerene C₇₈, fullerene C₈₀, fullerene C₈₂, fullerene C₈₄, fullerene C₉₀, fullerene C₉₆, fullerene C₂₄₀, fullerene C₅₄₀ and mixed fullerenes, and fullerene derivatives refer to compounds obtained by adding a substituent to these fullerenes. The substituent is preferably an alkyl group, an aryl group or a heterocyclic group. The compounds mentioned in JP 2007-123707 A are preferred fullerene derivatives.

The photoelectric conversion film preferably has a bulk heterojunction structure formed in such a state that the compound (A) is mixed with a fullerene or a fullerene derivative. The bulk heterojunction structure refers to a film in which an organic p-type compound (e.g., the compound (A)) and an organic n-type compound are mixed and dispersed in the photoelectric conversion film. The photoelectric conversion film can be formed by any of a wet process and a dry process but is preferably formed by a codeposition process. By incorporating the heterojunction structure, the photoelectric conversion efficiency of the photoelectric conversion film can be improved while compensating for the short carrier diffusion length of the photoelectric conversion film. The bulk heterojunction structure is described in detail, for example, in paragraphs [0013] to of JP 2005-303266 A.

In terms of the responsiveness of the photoelectric conversion element, the content ratio of the fullerene-based compound to the sum of the photoelectric conversion material of the invention (compound (A)) and the fullerene-based compound (the film thickness of the fullerene-based compound calculated as a single layer/(the film thickness of the photoelectric conversion material of the invention (compound (A)) calculated as a single layer+the film thickness of the fullerene-based compound calculated as a single layer)) is preferably at least 50 vol %, more preferably at least 55 vol %, even more preferably at least 60 vol %, and most preferably at least 65 vol %. The upper limit is not particularly limited and is preferably up to 95 vol and more preferably up to 90 vol %.

The photoelectric conversion film in which the compound (A) according to the invention is mixed with the organic n-type compound is preferably a non-luminescent film and has characteristics different from the organic electroluminescent element (OLED). The non-luminescent film is a film having luminescent quantum efficiency of 1% or less, and the luminescent quantum efficiency is more preferably 0.5% or less and even more preferably 0.1% or less.

(Film Forming Method)

The photoelectric conversion film 12 can be formed by a dry film forming process or a wet film forming process. Specific examples of the dry film forming process include physical vapor deposition processes including vacuum deposition, sputtering, ion plating and molecular beam epitaxy (MBE), and chemical vapor deposition (CVD) processes such as plasma polymerization. Examples of the wet film forming process that may be used include casting, spin coating, dipping and a Langmuir-Blodgett (LB) process. Dry film forming processes are preferable and vacuum deposition is more preferable. In cases where a film is formed by vacuum deposition, the manufacturing conditions such as the degree of vacuum and deposition temperature can be set according to a common method.

The thickness of the photoelectric conversion film 12 is preferably at least 10 nm but up to 1,000 nm, more preferably at least 50 nm but up to 800 nm and most preferably at least 100 nm but up to 500 nm. An appropriate dark current suppressing effect is obtained by adjusting the thickness to 10 nm or more and an appropriate photoelectric conversion efficiency is obtained by adjusting the thickness to 1,000 nm or less.

[Electrode]

The electrodes (upper electrode (transparent conductive film) 15 and the lower electrode (conductive film) 11) are formed of conductive materials. Exemplary conductive materials that may be used include metals, alloys, metal oxides, electrically conductive compounds, and mixtures thereof.

Since light enters from the upper electrode 15, the upper electrode 15 is to be sufficiently transparent with respect to light to be detected. More specifically, exemplary materials of the upper electrode include conductive metal oxides such as tin oxide doped with antimony or fluorine (ATO, FTO), tin oxide, zinc oxide, indium oxide, indium tin oxide (ITO), and indium zinc oxide (IZO); thin films of metals such as gold, silver, chromium and nickel; mixtures or laminates of these metals and the conductive metal oxides; inorganic conductive substances such as copper iodide and copper sulfide; organic conductive materials such as polyaniline, polythiophene and polypyrrole; and laminates of these materials and ITO. Of these, transparent conductive metal oxides are preferred in terms of high electrical conductivity and transparency.

When the transparent conductive film made of s transparent conducting oxide (TCO) is used as the upper electrode 15, DC short circuit or an increase in leakage current may occur. One of the causes is considered to be as follows: fine cracks introduced into the photoelectric conversion film 12 are covered with a compact TCO or other film to increase the conduction between the upper electrode 15 and the lower electrode 11 on the opposite side. Therefore, in the case of an aluminum electrode having comparatively poor film quality, the leakage current is less likely to increase. The increase in the leakage current can be considerably suppressed by controlling the film thickness of the upper electrode 15 with respect to the thickness (i.e., crack depth) of the photoelectric conversion film 12. It is desirable to adjust the thickness of the upper electrode 15 to one-fifth or less and preferably one-tenth or less of the thickness of the photoelectric conversion film 12.

Generally, the resistance value is abruptly increased by reducing the thickness of the conductive film below a certain range. However, the solid-state image sensor into which the photoelectric conversion element according to this embodiment is incorporated need only have a sheet resistance of preferably 100 to 10,000 Ω/square, and the film thickness has a high degree of freedom for thin film formation. The amount of absorbed light decreases with decreasing thickness of the upper electrode (transparent conductive film) 15 and the light transmission rate increases in general. The increase in the light transmission rate increases light absorption in the photoelectric conversion film 12 and hence the photoelectric conversion capacity, and is therefore very preferable. In consideration of the suppressed leakage current, increased thin film resistance value and increased transmission rate as a result of the reduction in film thickness, the thickness of the upper electrode 15 is preferably from 5 to 100 nm and more preferably from 5 to 20 nm.

Depending on the intended use, the lower electrode 11 may have transparency or be formed of such a material as to reflect light instead of having transparency. More specifically, exemplary materials of the lower electrode include conductive metal oxides such as tin oxide doped with antimony or fluorine (ATO, FTO), tin oxide, zinc oxide, indium oxide, indium tin oxide (ITO), indium zinc oxide (IZO); metals such as gold, silver, chromium, nickel, titanium, tungsten and aluminum; conductive compounds such as oxides and nitrides of the illustrated metals (e.g., titanium nitride (TiN)); mixtures or laminates of these metals and the conductive metal oxides; inorganic conductive substances such as copper iodide and copper sulfide; organic conductive materials such as polyaniline, polythiophene and polypyrrole; and laminates of these materials and ITO or titanium nitride.

The method of forming the electrodes is not particularly limited and a suitable method can be selected in consideration of the suitability for the electrode material. More specifically, the electrodes can be formed by wet processes such as a printing process and a coating process, physical processes such as a vacuum deposition process, a sputtering process and an ion plating process, and chemical processes such as CVD and plasma CVD.

When the material of the electrodes is ITO, the electrodes can be formed by processes such as an electron beam process, a sputtering process, a resistance heating vapor deposition process, a chemical reaction process (e.g., sol-gel process) and application of a dispersion of indium tin oxide. The film formed using ITO can be further subjected to UV-ozone treatment or plasma treatment. When the material of the electrodes is TIN, various processes including a reactive sputtering process are used and UV-ozone treatment or plasma treatment may be further performed.

[Charge Blocking Layers: Electron Blocking Layer and Hole Blocking Layer]

The photoelectric conversion element of the invention may have a charge blocking layer. The presence of this layer allows the resulting photoelectric conversion element to have more excellent characteristics (e.g., photoelectric conversion efficiency and response speed). Examples of the charge blocking layer include an electron blocking layer and a hole blocking layer. The respective layers are described below in detail.

[Electron Blocking Layer]

Electron donating organic materials can be used for the electron blocking layer. More specifically, as low molecular weight materials, it is possible to use aromatic diamine compounds such as N,N-bis(3-methylphenyl)-(1,1′-biphenyl)-4,4′-diamine (TPD) and 4,4′-bis[N-(naphthyl)-N-phenyl-amino]biphenyl (α-NPD), oxazole, oxadiazole, triazole, imidazole, imidazolone, stilbene derivatives, pyrazoline derivatives, tetrahydroimidazole, polyarylalkane, butadiene, 4,4′,4″-tris(N-(3-methylphenyl)N-phenylamino)triphenylamine (m-MTDATA), porphyrin compounds such as porphyrin, tetraphenylporphyrin copper, phthalocyanine, copper phthalocyanine, and titanium phthalocyanine oxide, triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, silazane derivatives, and the like. As high molecular weight materials, it is possible to use polymers such as phenylene vinylene, fluorene, carbazole, indole, pyrene, pyrrole, picoline, thiophene, acetylene and diacetylene, and derivatives thereof. Compounds that are not electron donating compounds can also be used as long as they have sufficient hole transport properties and electron blocking properties. In terms of suppressing the dark current, the difference between the electron affinity of the n-type semiconductor used in the photoelectric conversion film and the ionization potential of the material used in the electron blocking layer adjacent to the photoelectric conversion film is preferably 1 eV or more. In a case where fullerene (C₆₀) is used as the n-type semiconductor, the material for use in the adjacent electron blocking layer preferably has an ionization potential of 5.2 eV or more because fullerene (C₆₀) has an electron affinity of 4.2 eV. More specifically, compounds as mentioned in paragraphs [0083] to [0089] of JP 2008-72090 A, paragraphs [0049] to [0063] of JP 2011-176259 A, paragraphs to [0156] of JP 2011-228614 A, and paragraphs [0108] to of JP 2011-228615 A are preferable.

The electron blocking layer may be of a multi-layered structure.

Inorganic materials may also be used for the electron blocking layer. Generally, inorganic materials have a higher dielectric constant than organic materials. Accordingly, when inorganic materials are used for the electron blocking layer, a higher voltage is applied to the photoelectric conversion film, and hence the photoelectric conversion efficiency can be increased. Exemplary materials that may be used to form the electron blocking layer include calcium oxide, chromium oxide, copper chromium oxide, manganese oxide, cobalt oxide, nickel oxide, copper oxide, copper gallium oxide, copper strontium oxide, niobium oxide, molybdenum oxide, copper indium oxide, silver indium oxide, and iridium oxide. In the electron blocking layer of a single layer structure, this layer may be an inorganic material layer, and in the electron blocking layer of a multi-layer structure, one or more than one sublayer of the electron blocking layer may be made of an inorganic material.

[Hole Blocking Layer]

An electron accepting organic material can be used for the hole blocking layer.

Examples of the electron accepting material that may be used include an oxadiazole derivative such as 1,3-bis(4-tert-butylphenyl-1,3,4-oxadiazolyl)phenylene (OXD-7), an anthraquinodimethane derivative, a diphenylquinone derivative, bathocuproine, bathophenanthroline and derivatives thereof, a triazole compound, a tris(8-hydroxyquinolinato)aluminum complex, a bis(4-methyl-8-quinolinato)aluminum complex, a distyrylarylene derivative and a silole compound. A material other than the electron accepting organic material can be used as long as the material has sufficient electron transport properties. Use may be made of a porphyrin compound, a styryl compound such as DCM (4-dicyanomethylene-2-methyl-6-(4-(dimethylaminostyryl))-4H pyran) and a 4H pyran compound. More specifically, compounds mentioned in paragraphs [0073] to [0078] of JP 2008-72090 A are preferable.

The method of manufacturing the charge blocking layer is not particularly limited and the charge blocking layer may be formed by a dry film forming process or a wet film forming process. Examples of the dry film forming process that can be used include vapor deposition and sputtering. Vapor deposition may be performed by physical vapor deposition (PVD) or chemical vapor deposition (CVD) but physical vapor deposition such as vacuum deposition is preferable. Examples of the wet film forming process that can be used include an ink-jet process, a spraying process, a nozzle printing process, a spin coating process, a dip coating process, a casting process, a die coating process, a roll coating process, a bar coating process and a gravure coating process, and an ink-jet process is preferable in terms of high precision patterning.

The charge blocking layers (electron blocking layer and hole blocking layer) preferably each have a thickness of 10 to 200 nm, more preferably 30 to 150 nm and most preferably 50 to 100 nm because too small a thickness will reduce the effect of suppressing the dark current and too large a thickness will reduce the photoelectric conversion efficiency.

[Substrate]

The photoelectric conversion element of the invention may further include a substrate. The type of the substrate used is not particularly limited and a semiconductor substrate, a glass substrate or a plastic substrate may be used.

Although the position of the substrate is not particularly limited, the conductive film, the photoelectric conversion film and the transparent conductive film are usually formed on the substrate in this order.

[Sealing Layer]

The photoelectric conversion element of the invention may further include a sealing layer. The performance of the photoelectric conversion material may be considerably deteriorated by the presence of deterioration factors such as water molecules and such deterioration can be prevented by coating and sealing the whole of the photoelectric conversion film with a sealing layer made of a compact material which is impermeable to water molecules, as exemplified by a ceramic material such as a metal oxide, a metal nitride or a metal oxynitride, or diamond-like carbon (DLC).

The selection of a suitable material and the manufacture of the sealing layer may be performed according to the description in paragraphs [0210] to [0215] of JP 2011-082508 A.

[Optical Sensor]

Exemplary uses of the photoelectric conversion element include a photoelectric cell and an optical sensor, and the photoelectric conversion element of the invention is preferably used as an optical sensor. The photoelectric conversion element may be singly used for the optical sensor, and a line sensor having the photoelectric conversion elements in a linear arrangement and a two-dimensional sensor having the photoelectric conversion elements arranged on a plane are preferable. The photoelectric conversion element of the invention functions as an image sensor, in the line sensor by converting light image information to electric signals using an optical system and a drive portion as in a scanner and in the two-dimensional sensor by converting light image information to electric signals through imaging on a sensor with an optical system as in an imaging module.

Since the photoelectric cell is a power generating device, the efficiency of conversion of light energy to electrical energy is important performance but the dark current which is the current in a dark place does not cause any functional problem. In addition, the photoelectric cell does not need a subsequent heating step for disposing color filters or other operations. Since converting a bright and dark signal to an electric signal with a high degree of accuracy is important performance of the optical sensor, the efficiency at which the quantity of light is converted to current is also important performance. However, output of a signal in a dark place causes a noise and therefore a low dark current is required. In addition, the resistance to the subsequent step is also important.

[Image Sensor]

Next, an exemplary configuration of an image sensor including the photoelectric conversion element 10a is described.

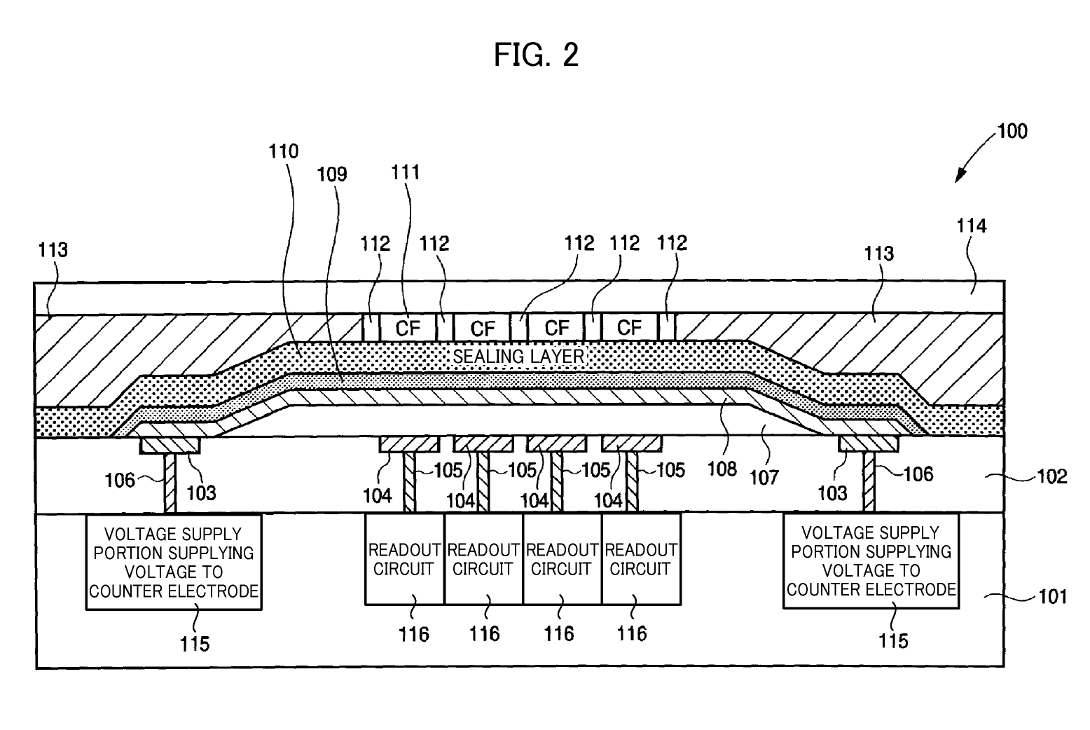

In the exemplary configuration to be described below, the description is simplified or omitted by using the same or corresponding numerals in FIG. 2 to show the members of which the configuration and the operation are equivalent to those of the members already described above.

The image sensor is a device for converting light information of an image to electric signals and refers to a device in which a plurality of photoelectric conversion elements are disposed in a matrix on the same plane and an electric signal obtained by conversion of a light signal in each of the photoelectric conversion elements (pixels) can be sequentially outputted for each pixel outside the image sensor. Therefore, each pixel is composed of one photoelectric conversion element and one or more transistors.

FIG. 2 is a schematic cross-sectional view showing a schematic configuration of an image sensor for illustrating an embodiment of the invention. This image sensor is used by being mounted on an imaging module of an imaging device such as a digital camera or a digital video camera, an electronic endoscope or a mobile phone.

The image sensor includes a plurality of photoelectric conversion elements configured as shown in FIG. 1A or 1B and a circuit board having formed therein readout circuits for reading out signals corresponding to charges generated in the photoelectric conversion films of the respective photoelectric conversion elements, and has such a configuration that the photoelectric conversion elements are in a one-dimensional or two-dimensional array on the same plane above the circuit board.

An image sensor 100 shown in FIG. 2 includes a substrate 101, an insulating layer 102, connection electrodes 103, pixel electrodes (lower electrodes) 104, connecting portions 105, connecting portions 106, a photoelectric conversion film 107, a counter electrode (upper electrode) 108, a buffer layer 109, a sealing layer 110, color filters (CFs) 111, partition walls 112, a light-shielding layer 113, a protective layer 114, counter electrode voltage supply portions 115 and readout circuits 116.

The pixel electrodes 104 have the same function as the lower electrode 11 of the photoelectric conversion element 10a shown in FIG. 1A. The counter electrode 108 has the same function as the upper electrode 15 of the photoelectric conversion element 10a shown in FIG. 1A. The photoelectric conversion film 107 has the same configuration as the layer provided between the lower electrode 11 and the upper electrode 15 of the photoelectric conversion element 10a shown in FIG. 1A.

The substrate 101 is a glass substrate or a semiconductor substrate made of, for example, silicon. The insulating layer 102 is formed on the substrate 101. The pixel electrodes 104 and the connection electrodes 103 are formed at a surface of the insulating layer 102.

The photoelectric conversion film 107 is a layer which is formed so as to cover the pixel electrodes 104 and is common to all the photoelectric conversion elements.

The counter electrode 108 is an electrode which is formed on the photoelectric conversion film 107 and is common to all the photoelectric conversion elements. The counter electrode 108 is also formed on the connection electrodes 103 disposed outside the photoelectric conversion film 107 and is electrically connected to the connection electrodes 103.

The connecting portions 106 are plugs or other parts buried in the insulating layer 102 to electrically connect the connection electrodes 103 with the counter electrode voltage supply portions 115. The counter electrode voltage supply portions 115 are formed in the substrate 101 and apply a predetermined voltage to the counter electrode 108 through the connecting portions 106 and the connection electrodes 103. In cases where the voltage to be applied to the counter electrode 108 is higher than the power supply voltage of the image sensor, the predetermined voltage is supplied by increasing the power supply voltage with a booster circuit such as a charge pump.

The readout circuits 116 are formed in the substrate 101 so as to correspond to the respective pixel electrodes 104 to read out signals corresponding to the charges collected by the corresponding pixel electrodes 104. The readout circuits 116 are configured using, for example, CCDs, CMOS circuits or TFT circuits, and are shielded by a light-shielding layer (not shown) disposed in the insulating layer 102. The readout circuits 116 are electrically connected to the corresponding pixel electrodes 104 through the connecting portions 105.

The buffer layer 109 is formed on the counter electrode 108 so as to cover the counter electrode 108. The sealing layer 110 is formed on the buffer layer 109 so as to cover the buffer layer 109. The color filters 111 are formed on the sealing layer 110 at such positions as to face the respective pixel electrodes 104. The partition walls 112 are formed between the adjacent color filters 111 to improve the light transmission efficiency of the color filters 111.

The light-shielding layer 113 is formed on the sealing layer 110 in the regions other than those where the color filters 111 and the partition walls 112 are formed and prevents light from entering the photoelectric conversion film 107 formed in the regions other than the effective pixel regions. The protective layer 114 is formed on the color filters 111, the partition walls 112 and the light-shielding layer 113 and protects the whole of the image sensor 100.

When light enters the thus configured image sensor 100, the light enters the photoelectric conversion film 107 to generate charges. Of the generated charges, the holes are collected by the pixel electrodes 104 and the voltage signals corresponding to the amounts of the collected holes are outputted outside the image sensor 100 by the readout circuits 116.

The method of manufacturing the image sensor 100 is as follows:

On the circuit board having the counter electrode voltage supply portions 115 and the readout circuits 116 formed therein, the connecting portions 105 and 106, the connection electrodes 103, the pixel electrodes 104 and the insulating layer 102 are formed. The pixel electrodes 104 are formed at a surface of the insulating layer 102 in a, for example, square grid shape.

Next, the photoelectric conversion film 107 is formed on the pixel electrodes 104, for example, by vacuum heating vapor deposition. Next, the counter electrode 108 is formed on the photoelectric conversion film 107 under vacuum, for example, by sputtering. Next, the buffer layer 109 and the sealing layer 110 are formed in succession on the counter electrode 108, for example, by vacuum heating vapor deposition. Next, the color filters 111, the partition walls 112 and the light-shielding layer 113 are formed, and the protective layer 114 is then formed to complete the image sensor 100.

In the method of manufacturing the image sensor 100, the photoelectric conversion elements can also be prevented from deteriorating in performance by adding a step of putting the image sensor 100 under manufacture into a non-vacuum state between the step of forming the photoelectric conversion film 107 and the step of forming the sealing layer 110. The manufacturing cost can be suppressed while preventing the image sensor 100 from deteriorating in performance by adding this step.

### EXAMPLES

Examples are shown below but the invention should not be construed as being limited to these examples.

### Example 1-1

A photoelectric conversion element having the form of FIG. 1A was prepared. The photoelectric conversion element includes a lower electrode 11, an electron blocking layer 16A, a photoelectric conversion film 12 and an upper electrode 15.

More specifically, an amorphous ITO film was deposited on a glass substrate by sputtering to form the lower electrode 11 (thickness: 30 nm), and a compound (EB-1) shown below was then deposited on the lower electrode 11 by vacuum heating vapor deposition to form the electron blocking layer 16A (thickness: 100 nm). In addition, with the substrate temperature controlled to 25° C., a compound (1) shown below and fullerene (C₆₀) were codeposited on the electron blocking layer 16A by vacuum heating vapor deposition to thicknesses of 114 nm and 286 nm on a single layer basis, respectively, thereby forming the photoelectric conversion film 12. Moreover, an amorphous ITO film was deposited on the photoelectric conversion film 12 by sputtering to form the upper electrode 15 (transparent conductive film) (thickness: 10 nm). A SiO film was formed on the upper electrode 15 by heating vapor deposition as the sealing layer and an aluminum oxide (Al₂O₃) layer was then formed on the SiO film by ALCVD, thereby preparing the photoelectric conversion element. Vapor deposition was carried out by heating a crucible under vacuum (degree of vacuum: 4×10⁻¹ Pa or less).

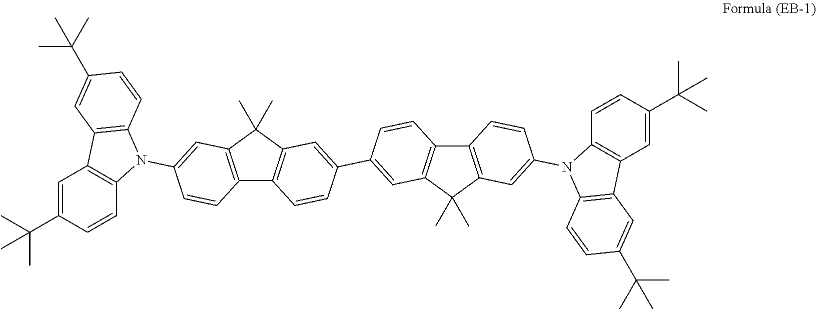 [SMILES: CC(C)(C)c1ccc2c(c1)c1cc(C(C)(C)C)ccc1n2-c1ccc2c(c1)C(C)(C)c1cc(-c3ccc4c(c3)C(C)(C)c3cc(-n5c6ccc(C(C)(C)C)cc6c6cc(C(C)(C)C)ccc65)ccc3-4)ccc1-2]

### Examples 1-2 to 1-5 and Comparative Examples 1-1 to 1-5

The procedure of Example 1-1 was repeated except that the compound (1) was replaced by compounds (2) to (5) and comparative compounds (1) to (5), thereby preparing photoelectric conversion elements.

The compounds (1) to (5) shown below correspond to the compound (A) represented by formula (1) shown above.

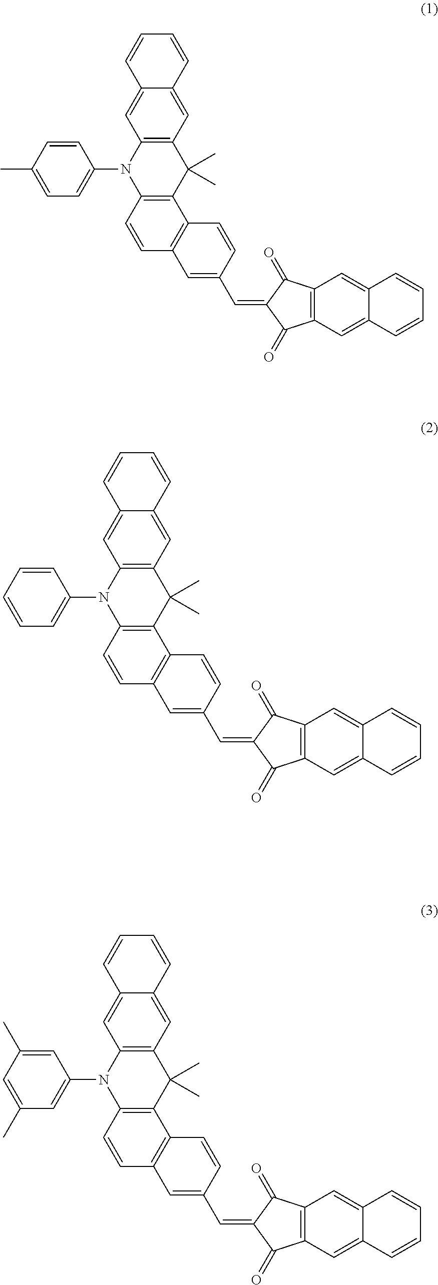 [SMILES: Cc1ccc(N2c3cc4ccccc4cc3C(C)(C)c3c2ccc2cc(C=C4C(=O)c5cc6ccccc6cc5C4=O)ccc32)cc1 ; CC1(C)c2cc3ccccc3cc2N(c2ccccc2)c2ccc3cc(C=C4C(=O)c5cc6ccccc6cc5C4=O)ccc3c21 ; Cc1cc(C)cc(N2c3cc4ccccc4cc3C(C)(C)c3c2ccc2cc(C=C4C(=O)c5cc6ccccc6cc5C4=O)ccc32)c1]

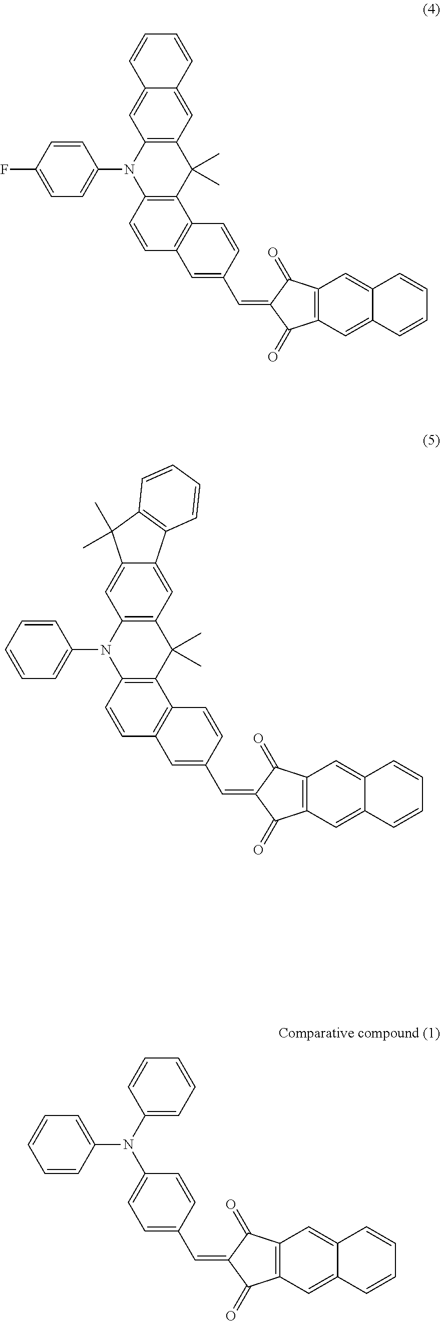 [SMILES: CC1(C)c2cc3ccccc3cc2N(c2ccc(F)cc2)c2ccc3cc(C=C4C(=O)c5cc6ccccc6cc5C4=O)ccc3c21 ; CC1(C)c2ccccc2-c2cc3c(cc21)N(c1ccccc1)c1ccc2cc(C=C4C(=O)c5cc6ccccc6cc5C4=O)ccc2c1C3(C)C ; O=C1C(=Cc2ccc(N(c3ccccc3)c3ccccc3)cc2)C(=O)c2cc3ccccc3cc21]

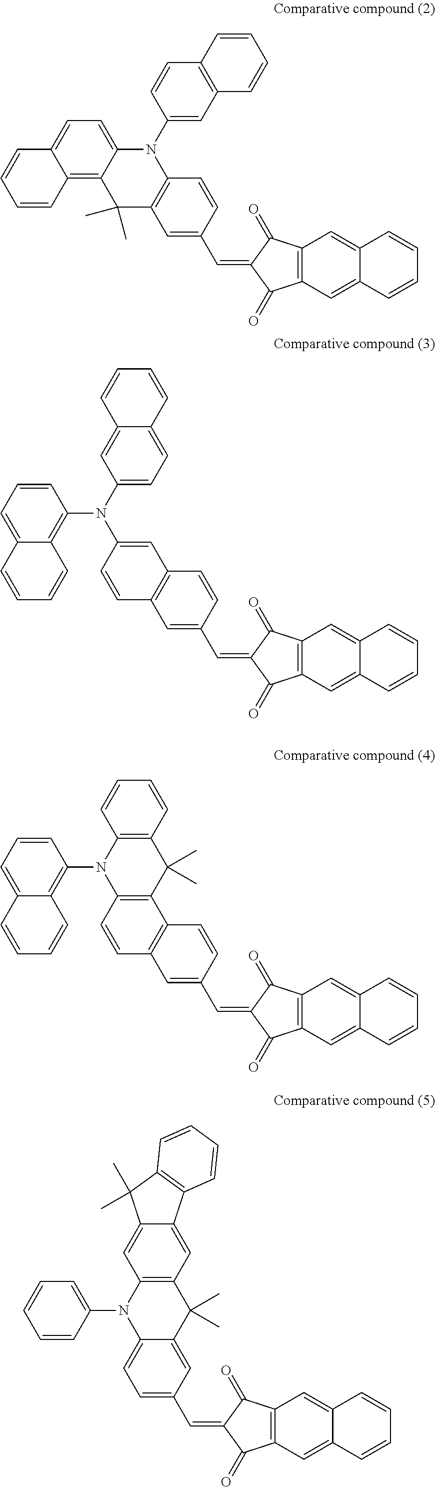 [SMILES: CC1(C)c2cc(C=C3C(=O)c4cc5ccccc5cc4C3=O)ccc2N(c2ccc3ccccc3c2)c2ccc3ccccc3c21 ; O=C1C(=Cc2ccc3cc(N(c4ccc5ccccc5c4)c4cccc5ccccc45)ccc3c2)C(=O)c2cc3ccccc3cc21 ; CC1(C)c2ccccc2N(c2cccc3ccccc23)c2ccc3cc(C=C4C(=O)c5cc6ccccc6cc5C4=O)ccc3c21 ; CC1(C)c2ccccc2-c2cc3c(cc21)N(c1ccccc1)c1ccc(C=C2C(=O)c4cc5ccccc5cc4C2=O)cc1C3(C)C]

The compounds (1) to (5) were synthesized by using a known method. The compounds were identified by MS measurement and ¹H-NMR measurement.

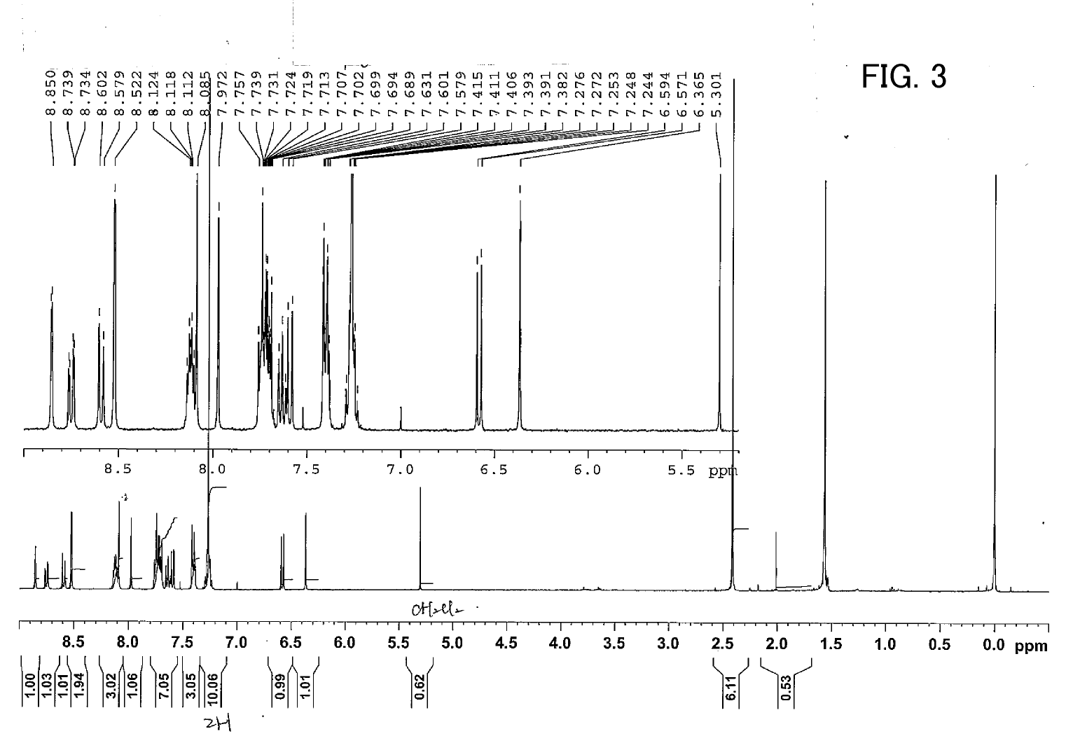

A specific synthesis scheme of the compound (2) is shown below. FIG. 3 shows a ¹H-NMR spectrum of the compound (2).

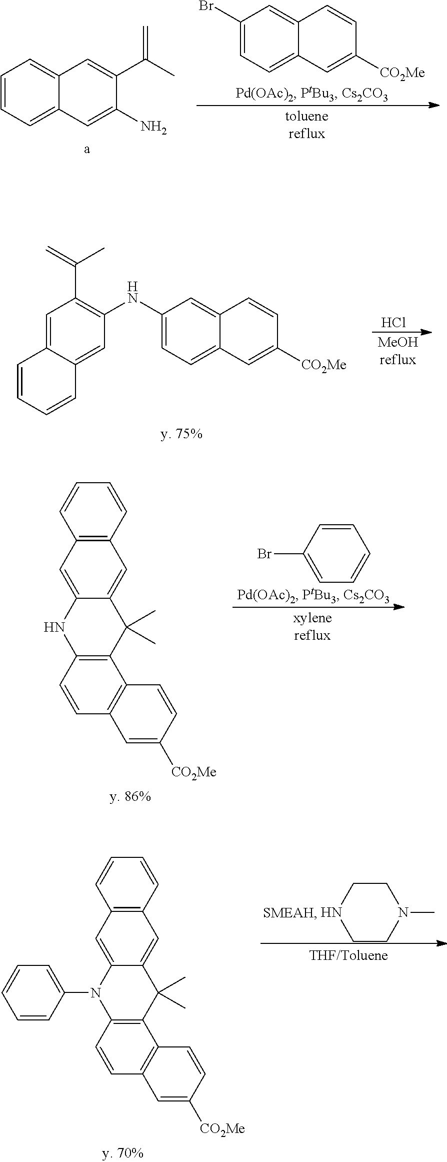

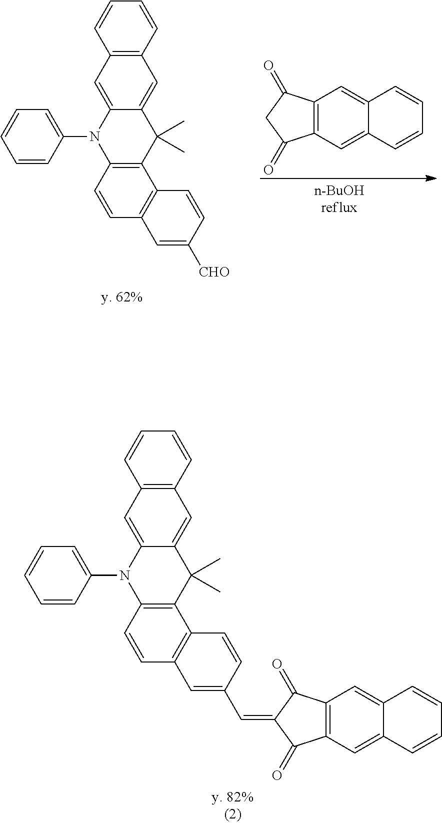 [SMILES: CC1(C)c2cc3ccccc3cc2N(c2ccccc2)c2ccc3cc(C=O)ccc3c21 ; O=C1CC(=O)c2cc3ccccc3cc21 ; CC1(C)c2cc3ccccc3cc2N(c2ccccc2)c2ccc3cc(C=C4C(=O)c5cc6ccccc6cc5C4=O)ccc3c21]

The compound (2) was synthesized according to the scheme shown above. In the above scheme, a compound represented by a was synthesized by the method described in Tetrahedron 63 (2007) 2153-2160. SMEAH in the scheme represents sodium bis(2-methoxyethoxy)aluminum dihydride.

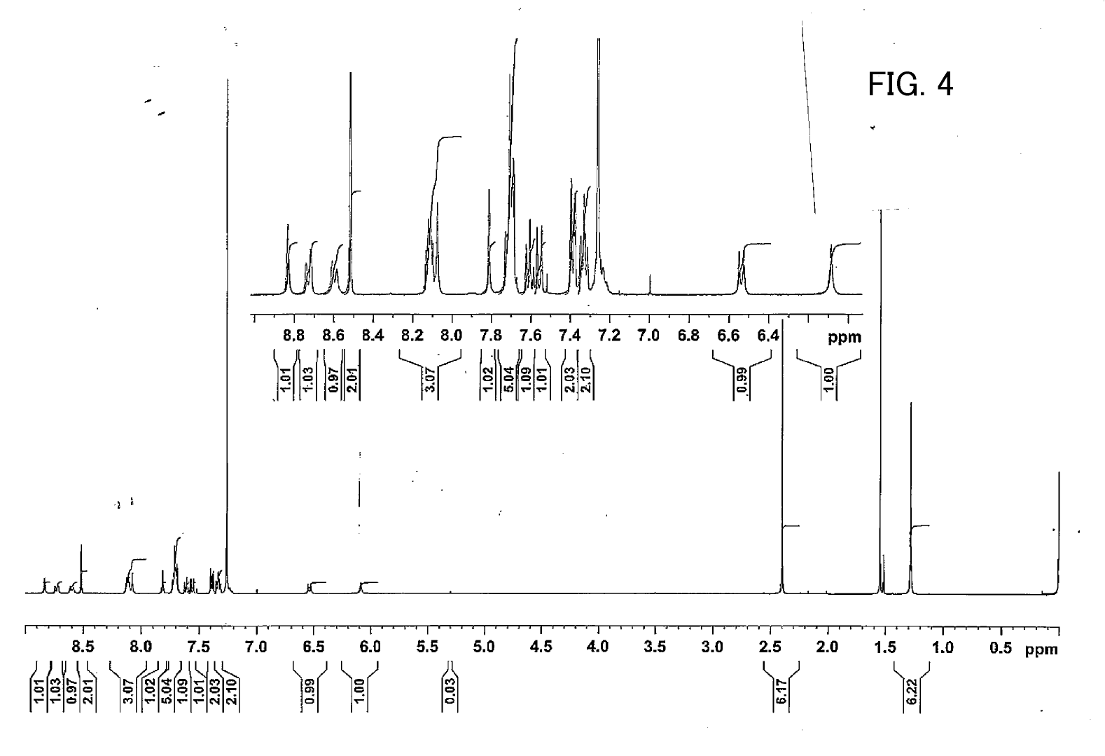

A specific synthesis scheme of the compound (5) is shown below. FIG. 4 shows a ¹H-NMR spectrum of the compound (5).

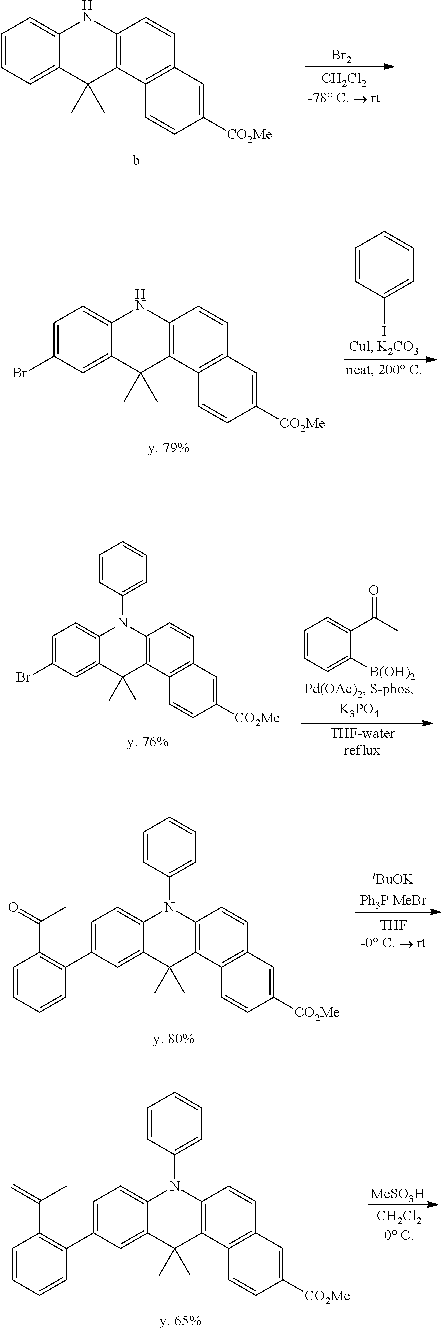

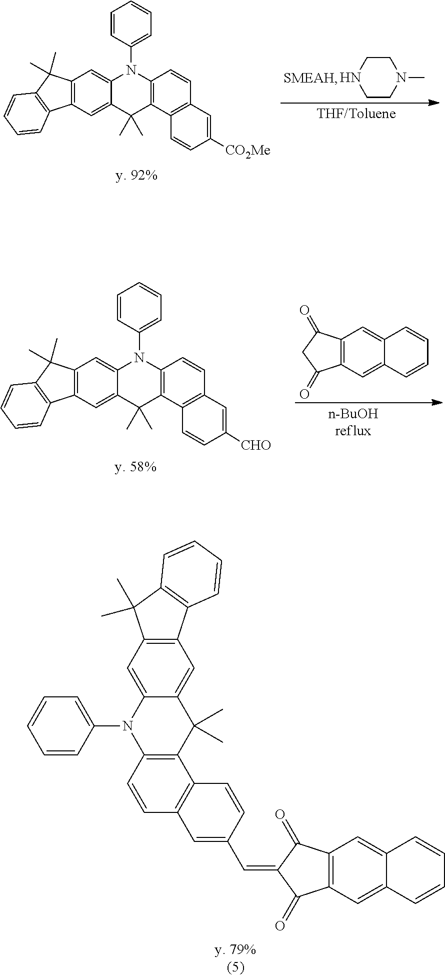

The compound (5) was synthesized according to the scheme shown above. In the above scheme, a compound represented by b was synthesized by the method described in JP 2012-77064 A.

### Example 2-1

The procedure of Example 1-1 was repeated except that the compound (1) and the fullerene (C₆₀) were codeposited by vacuum heating vapor deposition to thicknesses of 200 nm and 200 nm on a single layer basis, respectively, instead of codepositing the compound (1) and the fullerene (C₆₀) by vacuum heating vapor deposition to thicknesses of 114 nm and 286 nm on a single layer basis, respectively, thereby preparing a photoelectric conversion element.

### Example 2-2

The procedure of Example 1-1 was repeated except that the compound (1) and the fullerene (C₆₀) were codeposited by vacuum heating vapor deposition to thicknesses of 160 nm and 240 nm on a single layer basis, respectively, instead of codepositing the compound (1) and the fullerene (C₆₀) by vacuum heating vapor deposition to thicknesses of 114 nm and 286 nm on a single layer basis, respectively, thereby preparing a photoelectric conversion element.

<Check of Element Drive>

It was checked whether each of the resulting photoelectric conversion elements functioned as the photoelectric conversion element. To be more specific, a voltage was applied to the lower electrode and the upper electrode of each of the resulting photoelectric conversion elements to have an electric field intensity of 2.5×10⁵ V/cm and current values in a dark place and a bright place were measured. As a result, each of the photoelectric conversion elements showed a dark current of 100 nA/cm² or less in the dark place but showed a current of 10 μA/cm² or more in the bright place, and it was confirmed that they functioned as the photoelectric conversion elements.

<Evaluation of Responsiveness>

Each of the resulting photoelectric conversion elements was evaluated for the responsiveness.

To be more specific, an electric field of 1.5×10⁵ V/cm was applied to each of the photoelectric conversion elements and the photocurrent upon light irradiation from the side of the upper electrode (transparent conductive film) was measured to determine the rise time of the signal intensity from 0% to 98%. As a result, a sample was rated as A when the value relative to the rise time in Example 1-1 which was taken as 1 was up to 1.1, rated as B when the relative value was more than 1.1 but up to 1.3, rated as C when the relative value was more than 1.3 but up to 2.0, and rated as D when the relative value was more than 2.0. The results are shown in Table 1. From a practical point of view, the rating is preferably A or B and more preferably A.

The relative value is calculated by the following expression:

(Relative value)=(rise time of signal intensity from 0% to 98% in each of Examples or each of Comparative Examples/rise time of signal intensity from 0% to 98% in Example 1-1)

<Evaluation of Photoelectric Conversion Efficiency (External Quantum Efficiency)>

Each of the resulting photoelectric conversion elements was evaluated for the photoelectric conversion efficiency.

To be more specific, a voltage was applied to the lower electrode and the upper electrode of each of the resulting photoelectric conversion elements to have an electric field intensity of 2.0×10⁵ V/cm and the external quantum efficiency at a wavelength of 580 nm was measured at this voltage. As a result, a sample was rated as A when the value relative to the external quantum efficiency in Example 1-1 which was taken as 1 was 0.8 or more, rated as B when the relative value was less than 0.8 but at least 0.7, and rated as C when the relative value was less than 0.7. The results are shown in Table 1. From a practical point of view, the rating is preferably A.

In Table 1, “C₆₀ content” was calculated by the following expression:

(C₆₀ content)=(thickness of fullerene (C₆₀) film on a single layer basis)/{(thickness of compound film on a single layer basis)+(thickness of fullerene (C₆₀) film on a single layer basis)}

TABLE 1

| | | | | Photoelectric |
|---|---|---|---|---|
| | | C₆₀ | Respon- | conversion |
| | Compound | content | siveness | efficiency |
| EX 1-1 | (1) | 72% | A | A |
| EX 1-2 | (2) | 72% | A | A |
| EX 1-3 | (3) | 72% | A | A |
| EX 1-4 | (4) | 72% | A | A |
| EX 1-5 | (5) | 72% | B | A |
| CE 1-1 | Comparative | 72% | A | C |
| | compound (1) | | | |
| CE 1-2 | Comparative | 72% | D | B |
| | compound (2) | | | |
| CE 1-3 | Comparative | 72% | A | C |
| | compound (3) | | | |
| CE 1-4 | Comparative | 72% | C | A |
| | compound (4) | | | |
| CE 1-5 | Comparative | 72% | D | B |
| | compound (5) | | | |
| EX 2-1 | (1) | 50% | B | A |
| EX 2-2 | (1) | 60% | A | A |

As is seen from Table 1, Examples in which the compounds (A) represented by formula (1) were used as the photoelectric conversion materials each showed excellent responsiveness and high photoelectric conversion efficiency.

The comparison of Examples 1-1 to 1-5 revealed that Examples 1-1 to 1-4 in which B₁ in formula (1) above was a 6-membered ring exhibited more excellent responsiveness.

The comparison of Examples 1-1, 2-1 and 2-2 revealed that Examples 1-1 and 2-2 in which the ratio of the fullerene-based compound content to the sum of the compound (A) content and the fullerene-based compound content was 60 vol % or more exhibited more excellent responsiveness.

On the other hand, in each of Comparative Examples 1-1, 1-2 and 1-5 in which a compound having no naphthalene ring in the linkage moiety was used as the photoelectric conversion material, the responsiveness and/or the photoelectric conversion efficiency was not sufficient.

In Comparative Example 1-3 using, as the photoelectric conversion material, a compound which had a naphthalene ring in the linkage moiety but in which the linkage moiety did not form a ring with an arylamine, the photoelectric conversion efficiency was not sufficient.

In Comparative Example 1-4 using, as the photoelectric conversion material, a compound which had a naphthalene ring in the linkage moiety and in which the linkage moiety and an arylamine were taken together to form a ring but a 5- or 6-membered ring was not fused to the benzene ring of the arylamine, the responsiveness was not sufficient.

<Preparation of Image Sensor>

An image sensor of the same form as shown in FIG. 2 was prepared. More specifically, amorphous TiN was deposited on a CMOS substrate to a thickness of 30 nm by sputtering to form a film, and the film was patterned by photolithography so that one pixel may exist on each photodiode (PD) on the CMOS substrate to form a lower electrode. The film formation using the electron blocking material and its subsequent steps were carried out in the same manner as in Examples 1-1 to 1-5, 2-1 and 2-2 and Comparative Examples 1-1 to 1-5. The evaluation was also made in the same manner and the same results as shown in Table 1 were obtained. It was revealed that the photoelectric conversion element of the invention also exhibits excellent performance as the image sensor.

What is claimed is:

1. A photoelectric conversion element comprising:
a conductive film;
a photoelectric conversion film containing a photoelectric conversion material; and
a transparent conductive film, the conductive film, the photoelectric conversion film and the transparent conductive film being formed in this order, and
the photoelectric conversion material containing a compound (A) represented by formula (1) 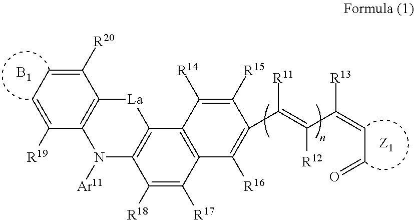
(in formula (1), R¹¹ to R¹³ each independently represent a hydrogen atom or a substituent; n represents an integer of 0 or more; R¹¹ and R¹² or R¹¹ and R¹³ may be taken together to form a ring; when n is 2 or more, a plurality of R¹¹s or R¹²s may be taken together to form a ring;
R¹⁴ to R²⁰ each independently represent a hydrogen atom or a substituent;
Ar¹¹ represents an optionally substituted aryl group or heteroaryl group; a substituent on Ar¹¹ may be taken together with R¹⁸ or R¹⁹ to form a ring;
La represents a group selected from the group consisting of >CR^{1a}R^{1b}, >NR^{1c}, an optionally substituted alkenylene group, —O—, —S—, and >SiR^{1c}R^{1e} where R^{1a}, R^{1b}, R^{1c}, R^{1d} and R^{1e} each independently represent a hydrogen atom or a substituent;
Z₁ is a ring containing at least two carbon atoms and represents a 5-membered ring, a 6-membered ring or a fused ring containing at least one of a 5-membered ring and a 6-membered ring; and
B₁ represents an optionally substituted 5- or 6-membered ring; and B¹ may further have a fused ring structure).

2. The photoelectric conversion element according to claim 1, wherein Z₁ in formula (1) is a ring represented by formula (Z1): 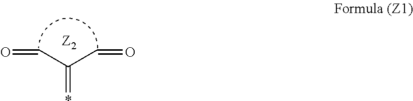 [SMILES: *=C(C=O)C=O]
(in formula (Z1), Z₂ is a ring containing at least three carbon atoms and represents a 5-membered ring, a 6-membered ring or a fused ring containing at least one of a 5-membered ring and a 6-membered ring; and * represents a bonding position with a carbon atom to which R¹³ in formula (1) is attached).

3. The photoelectric conversion element according to claim 1, wherein Ar¹¹ in formula (1) is an optionally substituted aryl group.

4. The photoelectric conversion element according to claim 1, wherein the compound (A) is a compound (a1) represented by formula (2) 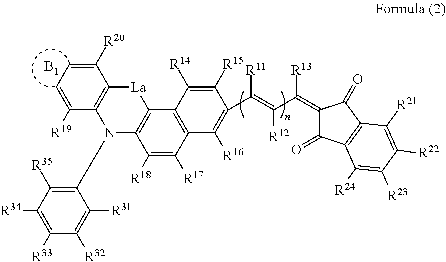
(in formula (2), R¹¹ to R¹³ each independently represent a hydrogen atom or a substituent; n represents an integer of 0 or more; R¹¹ and R¹² or R¹¹ and R¹³ may be taken together to form a ring; when n is 2 or more, a plurality of R¹¹s or R¹²s may be taken together to form a ring;
R¹⁴ to R²⁰ each independently represent a hydrogen atom or a substituent;
R²¹ to R²⁴ each independently represent a hydrogen atom or a substituent; R²¹ and R²², R²² and R²³ or R²³ and R²⁴ may be taken together to form a ring;
R³¹ to R³⁵ each independently represent a hydrogen atom or a substituent; R³¹ and R³², R³² and R³³, R³³ and R³⁴ or R³⁴ and R³⁵ may be taken together to form a ring;
La represents a group selected from the group consisting of >CR^{1a}R^{1b}, >NR^{1c}, an optionally substituted alkenylene group, —O—, —S—, and >SiR^{1d}R^{1e} where R^{1a}, R^{1b}, R^{1c}, R^{1d} and R^{1e} each independently represent a hydrogen atom or a substituent; and
B₁ represents an optionally substituted 5- or 6-membered ring; and B¹ may further have a fused ring structure).

5. The photoelectric conversion element according to claim 4, wherein n in formula (2) is 0.

6. The photoelectric conversion element according to claim 4, wherein La in formula (2) is a group represented by >CR^{1a}R^{1b} (where R^{1a} and R^{1b} each independently represent a hydrogen atom or a hydrocarbon group).

7. The photoelectric conversion element according to claim 4, wherein the compound (a1) is a compound (a2) represented by formula (3): 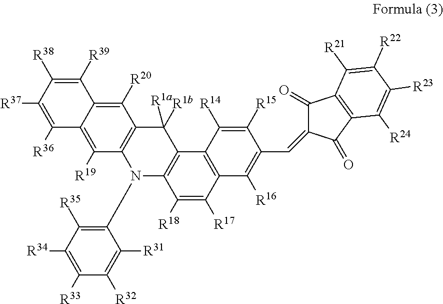
(in formula (3), R¹⁴ to R²⁰ each independently represent a hydrogen atom or a substituent;
R²¹ to R²⁴ each independently represent a hydrogen atom or a substituent; R²¹ and R²², R²² and R²³ or R²³ and R²⁴ may be taken together to form a ring;
R³¹ to R³⁵ each independently represent a hydrogen atom or a substituent; R³¹ and R³², R³² and R³³, R³³ and R³⁴ or R³⁴ and R³⁵ may be taken together to form a ring;
R³⁶ to R³⁹ each independently represent a hydrogen atom or a substituent; R³⁶ and R³⁷, R³⁷ and R³⁸ or R³⁸ and R³⁹ may be taken together to form a ring; and
R^{1a} and R^{1b} each independently represent a hydrogen atom or a substituent).

8. The photoelectric conversion element according to claim 1, wherein the photoelectric conversion film further contains an organic n-type semiconductor.

9. The photoelectric conversion element according to claim 8, wherein the organic n-type semiconductor contains a fullerene-based compound selected from the group consisting of fullerenes and fullerene derivatives.

10. The photoelectric conversion element according to claim 9, wherein a content ratio of the fullerene-based compound to a sum of the photoelectric conversion material and the fullerene-based compound (film thickness of the fullerene-based compound calculated as a single layer/(film thickness of the photoelectric conversion material calculated as a single layer+film thickness of the fullerene-based compound calculated as a single layer)) is at least 50 vol %.

11. The photoelectric conversion element according to claim 1, wherein a charge blocking layer is provided between the conductive film and the transparent conductive film.

12. The photoelectric conversion element according to claim 1, wherein the photoelectric conversion film is formed by vacuum deposition.

13. The photoelectric conversion element according to claim 1, wherein light is allowed to enter the photoelectric conversion film through the transparent conductive film.

14. The photoelectric conversion element according to claim 1, wherein the transparent conductive film comprises a transparent conductive metal oxide.

15. An optical sensor comprising the photoelectric conversion element according to claim 1.

16. An image sensor comprising the photoelectric conversion element according to claim 1.

17. A method of using the photoelectric conversion element according to claim 1,
wherein the conductive film and the transparent conductive film form an electrode pair and an electric field of 1×10⁻⁴ to 1×10⁷ V/cm is applied across the electrode pair.

18. The photoelectric conversion element according to claim 2, wherein Ar¹¹ in formula (1) is an optionally substituted aryl group.

19. The photoelectric conversion element according to claim 5, wherein La in formula (2) is a group represented by >CR^{1a}R^{1b} (where R^{1a} and R^{1b} each independently represent a hydrogen atom or a hydrocarbon group).

20. The photoelectric conversion element according to claim 2, wherein the photoelectric conversion film further contains an organic n-type semiconductor.
